(19) United States
(12) Patent Application Publication
(10) Pub. No.: US 2024/0113094 A1
(43) Pub. Date: Apr. 4, 2024

(54) GALVANIC ISOLATION DEVICE

(71) Applicant: Texas Instruments Incorporated, Dallas, TX (US)

(72) Inventors: Jeffrey Alan West, Plano, TX (US); Sreeram N. S., Bangalore (IN); Kashyap Barot, Bangalore (IN); Thomas Dyer Bonifield, Dallas, TX (US); Byron Lovell Williams, Plano, TX (US); Elizabeth Costner Stewart, Dallas, TX (US)

(21) Appl. No.: 17/957,847

(22) Filed: Sep. 30, 2022

(51) Int. Cl. H01L 25/18; H01F 27/28; H01F 27/29; H01F 27/32; H01L 23/00; H01L 27/01

(52) U.S. Cl. CPC H01L 25/18; H01F 27/2804; H01F 27/29; H01F 27/323; H01L 24/05; H01L 24/06; H01L 24/48; H01L 24/49; H01L 27/01; H01F 2027/2809; H01L 2224/05554; H01L 2224/05555; H01L 2224/05567; H01L 2224/05573; H01L 2224/05624; H01L 2224/05644; H01L 2224/06051; H01L 2224/06102; H01L 2224/06155; H01L 2224/0616; H01L 2224/4809; H01L 2224/48137; H01L 2224/48175; H01L 2224/4909

(57) ABSTRACT

A microelectronic device includes a galvanic isolation device on a silicon substrate and a semiconductor device on a semiconductor substrate. The galvanic isolation device includes a lower isolation element over the silicon substrate and an upper isolation element above the lower isolation element, separated by a dielectric plateau that comprises inorganic dielectric material extending from the lower isolation element to the upper isolation element. The galvanic isolation device includes lower bond pads connected to the lower isolation element adjacent to the dielectric plateau, and upper bond pads over the dielectric plateau, connected to the upper isolation element. The semiconductor device includes an active component, and device bond pads coupled to the active component. The microelectronic device includes first electrical connections to the lower bond pads and second electrical connections to the upper bond pads. The first electrical connections or the second electrical connections are connected to the device bond pads.

### TECHNICAL FIELD

This disclosure relates to the field of microelectronic devices. More particularly, but not exclusively, this disclosure relates to galvanic isolation devices in microelectronic devices.

### BACKGROUND

Galvanic isolation is a principle of isolating functional sections of electrical systems to prevent current flow while energy or information can still be exchanged between sections by other means, such as capacitance, induction, electromagnetic waves, optical, acoustic, or mechanical means. Galvanic isolation is typically used where two or more electric circuits communicate, but their grounds or reference nodes may be at different potentials. It is an effective method of breaking ground loops by preventing unwanted current from flowing between two units sharing a reference conductor. Galvanic isolation is also used for safety as a means of preventing accidental current from reaching ground through a person's body. Galvanic isolation devices are devices designed to minimize direct current and unwanted transient currents between two systems or circuits while allowing data and power transmission between the two. In most applications, galvanic isolation devices also act as a barrier to high voltage in addition to allowing the system to function properly. Dielectric breakdown is a key concern, especially in high-voltage applications. As the advances in the design of integrated circuits and semiconductor fabrication continue to take place, improvements in microelectronic devices, including galvanic isolation devices are also being concomitantly pursued.

### SUMMARY

The present disclosure introduces a galvanic isolation device on a silicon substrate. The galvanic isolation device includes a lower isolation element over the silicon substrate and an upper isolation element above the lower isolation element. The lower isolation element and the upper isolation element are parts of a high voltage isolation component of the galvanic isolation device. The galvanic isolation device includes a dielectric plateau over the lower isolation element. The dielectric plateau does not extend to a perimeter of the silicon substrate. The galvanic isolation device includes lower bond pads adjacent to the dielectric plateau; the lower bond pads are connected to the lower isolation element. The dielectric plateau does not extend to the lower bond pads. The upper isolation element is over the dielectric plateau. The galvanic isolation device includes upper bond pads over the dielectric plateau; the upper bond pads are connected to the upper isolation element. The dielectric plateau comprises inorganic dielectric material extending from the upper isolation element to the lower isolation element.

The present disclosure introduces a microelectronic device including the galvanic isolation device and a semiconductor device that is separate from the galvanic isolation device. The semiconductor device includes a semiconductor substrate separate from the silicon substrate, an active component in the semiconductor substrate, and device bond pads coupled to the active component. The microelectronic device further includes first electrical connections to the lower bond pads of the galvanic isolation device and second electrical connections to the upper bond pads of the galvanic isolation device. The device bond pads of the semiconductor device are connected to either the lower bond pads of the galvanic isolation device through the first electrical connections, or to the upper bond pads of the galvanic isolation device through the second electrical connections.

### BRIEF DESCRIPTION OF THE VIEWS OF THE DRAWINGS

FIG. 1A through FIG. 1C are top views and a cross section, respectively, of an example microelectronic device having a galvanic isolation device.

FIG. 2A through FIG. 2C are a top views and a cross section, respectively, of another example microelectronic device having two galvanic isolation devices.

FIG. 3A through FIG. 3C are a top views and a cross section, respectively, of a further example microelectronic device having two galvanic isolation devices.

FIG. 4A through FIG. 4E are a top views and a cross section, respectively, of a further example microelectronic device having two galvanic isolation devices.

FIG. 5 is a perspective view of an example galvanic isolation device (501) in a standalone configuration.

FIG. 6 is a top view of another example microelectronic device having two galvanic isolation devices.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

The following co-pending patent applications have related subject matter and are hereby incorporated by reference: U.S. patent application Ser. No. 15/xxx,xxx (Texas Instruments docket number T92886US01, titled “SINGLE DIE REINFORCED GALVANIC ISOLATION DEVICE”, by West, et al.), and U.S. patent application Ser. No. 15/xxx,xxx (Texas Instruments docket number T101074US01, titled “FIELD SUPPRESSION FEATURE FOR GALVANIC ISOLATION DEVICE”, by West, et al.), both filed simultaneously with this application. With their mention in this section, these patent applications are not admitted to be prior art with respect to the present invention.

The following co-pending patent applications have related subject matter and are hereby incorporated by reference: U.S. Provisional Patent Application No. 63/377,877 (Texas Instruments docket number TI-101057US01), U.S. Provisional Patent Application No. 63/411,934 (Texas Instruments docket number T92887US01), U.S. Provisional Patent Application No. 63/411,942 (Texas Instruments docket number T92904US01), U.S. Provisional Patent Application No. 63/411,952 (Texas Instruments docket number T100209US01), and U.S. Provisional Patent Application No. 63/411,961 (Texas Instruments docket number T102233US01), all filed simultaneously with this application. With their mention in this section, these patent applications are not admitted to be prior art with respect to the present invention.

A microelectronic device includes a galvanic isolation device and a semiconductor device. The galvanic isolation device includes a silicon substrate and a high voltage isolation component. The high voltage isolation component includes a lower isolation element. The galvanic isolation device includes a dielectric plateau formed over the lower isolation element, above the silicon substrate. The dielectric plateau does not extend to a perimeter of the silicon substrate, which may advantageously reduce bow or distortion of the silicon substrate due to stress in the dielectric material of the dielectric plateau. A further advantage of recessing the dielectric plateau from the perimeter of the silicon substrate may be accrued when singulating the galvanic isolation device; mechanical stress and small cracks caused by the singulation process may not extend into the dielectric plateau, avoiding a reliability degradation mechanism. The high voltage isolation component also includes an upper isolation element formed over the dielectric plateau, above the lower isolation element. In a disclosed example, the lower isolation element and the upper isolation element may be manifested as lower and upper transformer windings, respectively, and the high voltage isolation component may be manifested as an isolation transformer. In another disclosed example, the lower isolation element and the upper isolation element may be manifested as lower and upper capacitor plates, respectively, and the high voltage isolation component may be manifested as an isolation capacitor. In a further disclosed example, the lower isolation element and the upper isolation element may be manifested as a photodetector and photoemitter, respectively, and the high voltage isolation component may be manifested as an optical isolator. In another disclosed example, the lower isolation element and the upper isolation element may be manifested as a magnetic driver coil and a magnetic sensor, respectively, and the high voltage isolation component may be manifested as a magnetic isolator. Other manifestations of the lower isolation element, the upper isolation element, and the high voltage isolation component are within the scope of this disclosure. The lower isolation element and the upper isolation element are configured to transfer signals between the lower isolation element and the upper isolation element.

The galvanic isolation device includes lower bond pads connected to the lower isolation element. The lower bond pads are adjacent to the dielectric plateau, so that the dielectric plateau does not extend to the lower bond pads. The galvanic isolation device includes upper bond pads connected to the upper isolation element. The upper bond pads are over the dielectric plateau. The galvanic isolation device may include pattern fill conductors of the same conductive material used to form the lower isolation element, the lower bond pads, the upper isolation element and/or the upper bond pads. The pattern fill conductors may have tensile stress that may partially counteract compressive stress in the dielectric material of the dielectric plateau, advantageously reducing bow or distortion of the silicon substrate. The galvanic isolation device may include additional lower bond pads for bond shear tests, spaced at least 70 microns from the dielectric plateau, with 1 to 5 microns of dielectric material over adjacent interconnects to simultaneously protect the adjacent interconnects while not obstructing a bond shear test operation. The additional lower bond pads may advantageously enable the galvanic isolation device to meet device specifications requiring in situ bond shear tests.

The dielectric plateau comprises inorganic dielectric material extending from the upper isolation element to the lower isolation element, which may advantageously provide increased reliability compared to a comparable device having organic dielectric material such as polyimide, due to lower water uptake in the inorganic dielectric material and reduced charge injection rates in the inorganic dielectric material compared to the organic dielectric material A plateau thickness of the dielectric plateau between the upper isolation element and the lower isolation element is sufficient to provide reliable operation of the galvanic isolation device for an operational potential difference between the upper isolation element and the lower isolation element. The operational potential difference is at least 400 volts root-mean-square (rms). By way of example, the plateau thickness may be 18 microns to 22 microns for an operational potential difference of 1000 volts. The plateau thickness may be 6 microns to 10 microns for an operational potential difference of 400 volts rms. A vertical distance between the upper bond pads and the lower bond pads is approximately the thickness of the dielectric plateau between the upper isolation element and the lower isolation element.

The dielectric plateau may include sublayers of silicon dioxide-based dielectric material, such as dielectric material formed using tetraethyl orthosilicate (TEOS), formally named tetraethoxysilane. The sublayers of silicon dioxide-based dielectric material may include a first plurality of the sublayers formed by a first plasma enhanced chemical vapor deposition (PECVD) process and a second plurality of the sublayers formed by a second PECVD process, in which the first plurality of the sublayers have a higher stress than the second plurality of the sublayers. The lower stress in the second plurality of the sublayers may advantageously reduce bow or distortion of the silicon substrate. The first plurality of the sublayers may have a lower etch rate than the second plurality of the sublayers. The dielectric plateau may have a nitridated layer on lateral surfaces of the dielectric plateau, that is, on exposed surfaces of the sublayers of silicon dioxide-based dielectric material. The nitridated layer may reduce infiltration of water into the sublayers of silicon dioxide-based dielectric material.

The dielectric plateau may include a lower field reduction layer on the lower isolation element and an upper field reduction layer immediately under the upper isolation element. The lower field reduction layer may include one or more layers having dielectric constants greater than the sublayers of silicon dioxide-based dielectric material. Similarly, the upper field reduction layer may include one or more layers having dielectric constants greater than the sublayers of silicon dioxide-based dielectric material. The lower field reduction layer may reduce an electric field at the lower isolation element during operation of the galvanic isolation device, advantageously increasing a breakdown potential of the dielectric plateau. Similarly, the upper field reduction layer may reduce an electric field at the upper isolation element, advantageously increasing a breakdown potential of the dielectric plateau.

The galvanic isolation device may include a field diversion structure adjacent to the lower isolation element, connected to the silicon substrate. The field diversion structure is electrically conductive and inorganic. A top surface of the field diversion structure is at least as high as a bottom surface of a top conductor layer in the lower isolation element. The top surface of the field diversion structure does not extend past an upper surface of the top conductor layer in the lower isolation element. The field diversion structure is separated from the lower isolation element by a distance that is from half a thickness of the lower isolation element to twice the thickness of the lower isolation element. The field diversion structure may divert the electric field away from edges of the lower isolation element toward adjacent areas of the silicon substrate during operation of the galvanic isolation device, advantageously increasing the breakdown potential at corners of the lower isolation element.

The galvanic isolation device may include two or more high voltage isolation components, providing separate isolated signal channels. In one aspect, the silicon substrate of the galvanic isolation device may be free of an active component, which may advantageously reduce fabrication cost and complexity of the galvanic isolation device. In another aspect, the lower isolation element may include an active component in the silicon substrate. In a further aspect, the silicon substrate may include an active component as part of a signal processing circuit connected to the lower isolation element.

The galvanic isolation device may be formed by forming the lower bond pads and at least a portion of the lower isolation element over the substrate. A portion of the lower isolation element may be formed on or in the substrate. A dielectric layer stack is formed over the lower bond pads and the lower isolation element. In one aspect of this disclosure, the upper isolation element and the upper bond pads may be formed over the dielectric layer stack, and the dielectric layer stack is subsequently patterned by an etch process to form the dielectric plateau, exposing the lower bond pads. In another aspect, a portion of the upper isolation element and/or the upper bond pads may be formed over the dielectric layer stack, before the dielectric layer stack is formed by the etch process. In a further aspect, the upper isolation element and the upper bond pads may be formed over the dielectric plateau after the dielectric layer stack is patterned by the etch process. Forming the upper isolation element may include placing a partially formed portion of the upper isolation element onto the dielectric plateau.

The semiconductor device of the microelectronic device includes a semiconductor substrate separate from the silicon substrate, an active component in the semiconductor substrate, and device bond pads coupled to the active component. The semiconductor device may be manifested as an integrated circuit, or as a discrete component. The semiconductor substrate may include silicon, gallium nitride or other III-N semiconductor material, or silicon carbide, by way of example. The semiconductor device has an interconnect region over the semiconductor substrate with one or more interconnect levels and dielectric sublayers. An interconnect region thickness of the interconnect region may be less than the plateau thickness, because the semiconductor device is not configured to accommodate signals having a potential difference close to the operational potential difference between the upper isolation element and the lower isolation element.

The microelectronic device further includes first electrical connections to the lower bond pads of the galvanic isolation device and second electrical connections to the upper bond pads of the galvanic isolation device. The device bond pads of the semiconductor device are connected to either the lower bond pads of the galvanic isolation device through the first electrical connections, or to the upper bond pads of the galvanic isolation device through the second electrical connections. The first electrical connections and the second electrical connections may be manifested as wire bonds, ribbon bonds, tape automated bonds (TAB s), clips soldered to the bond pads, conductors formed by additive manufacturing processes (sometimes referred to as three dimensional printing), or traces on a circuit board, by way of example. The microelectronic device may be manifested as a multi-chip module, also known as a hybrid integrated circuit, or a circuit board with the galvanic isolation device and the semiconductor device, by way of example. The microelectronic device further includes encapsulant material, which is electrically non-conductive, on the galvanic isolation device and the semiconductor device, surrounding the first electrical connections and the second electrical connections.

The microelectronic device may be formed by forming the first electrical connections to the lower bond pads and forming the second electrical connections to the upper bond pads, by a wire bond process, a ribbon bond process, a TAB process, or a clip solder process. Either the first electrical connections or the second electrical connections are formed on the device bond pads of the semiconductor device.

During operation of the microelectronic device, incoming signals are input to the galvanic isolation device. The galvanic isolation device generates voltage-shifted signals from the incoming signals, which are transferred to the semiconductor device through either the first or the second electrical connections. The incoming signals and the voltage-shifted signals have a potential difference close to the operational potential difference of the high voltage isolation component.

Generating the voltage-shifted signals with the combination of the galvanic isolation device and the semiconductor device may provide a lower cost of the microelectronic device compared to integrating a high voltage isolation component into the semiconductor device, because the interconnect region of the semiconductor device would have to be as thick as the dielectric plateau. Increasing the thickness of the interconnect region would cost significantly more than forming the dielectric plateau, because the thicker interconnect region would require a series of additional levels of interconnects and vias to connect the active components and the low voltage circuits to the device bond pads, in addition to a plurality of sublayers of dielectric material between the levels of interconnects, while the dielectric plateau has fewer dielectric sublayers and has no interconnects and vias.

A family of galvanic isolation devices having a range of operational potential differences may advantageously enable a corresponding family of microelectronic devices using substantially identical instances of the semiconductor device. Each member of the family of microelectronic devices may thus be operable to efficiently generate voltage-shifted signals from incoming signals at elevated potentials close the specific operational potential difference of corresponding galvanic isolation device, using a single design of the semiconductor device. Thus, a family of the semiconductor devices, which would entail significant design and fabrication costs, is not necessary.

The microelectronic device may include a second galvanic isolation device, to provide additional signal channels to the semiconductor device. The microelectronic device may include an additional semiconductor device, in which the first semiconductor device is coupled to the lower bond pads of the galvanic isolation device through the first electrical connections, and the second semiconductor device is coupled to the upper bond pads of the galvanic isolation device through the second electrical connections. The first semiconductor device may operate at a low bias potential with respect to ground, and the second semiconductor device may operate at a high bias potential close to the operational potential difference of the high voltage isolation component.

For the purposes of this disclosure, a structure or component that is disclosed as including “primarily” a substance has more than 50 percent, by weight, of that substance. For example, an interconnect that is disclosed to include primarily aluminum has more than 50 percent, by weight, of the element aluminum.

For the purposes of this disclosure, the term “silicon dioxide” includes dielectric material which is primarily silicon dioxide with a few percent of hydrogen, water, hydroxyl groups, fluorine, or other material, by weight. The term silicon dioxide includes dielectric material formed by a PECVD process using TEOS and oxygen. The term silicon dioxide also includes dielectric material formed by a high density plasma (HDP) process using silane and oxygen.

For the purposes of this disclosure, organic material includes carbon-based polymers such as polyimide, benzocyclobutene (BCB), polybenzoxazole (PBO), or epoxy. For the purposes of this disclosure, organic material further includes carbon-silicon-based polymers, commonly referred to as silicone, such as. polydimethylsiloxane (PDMS). For the purposes of this disclosure, organic material does not include organosilicate glass (OSG), also referred to as carbon-doped oxide (CDO), silicon carbide, silicon carbonitride, or silicon oxycarbonitride. For the purposes of this disclosure, organic material does not include silicon dioxide-based dielectric material formed from TEOS, methylsilsesquioxane (MSQ), or hydrogen silsesquioxane (HSQ).

For the purposes of this disclosure, the term “lateral” refers to a direction parallel to a plane of a substrate of the component under discussion. The term “vertical” is understood to refer to a direction perpendicular to the plane of the same substrate.

For the purposes of this disclosure, the term “active component” refers to a semiconductor component with a p-n junction. Examples of active components include metal oxide semiconductor (MOS) transistors, bipolar junction transistors, junction field effect transistors (JFETs), diodes, variable reactance capacitors (varactors), and silicon controlled rectifiers (SCRs).

It is noted that terms such as top, bottom, over, above, under, and below may be used in this disclosure. These terms should not be construed as limiting the position or orientation of a structure or element, but should be used to provide spatial relationship between structures or elements. Similarly, words such as “inward” and “outward” would refer to directions toward and away from, respectively, the geometric center of a device or area and designated parts thereof.

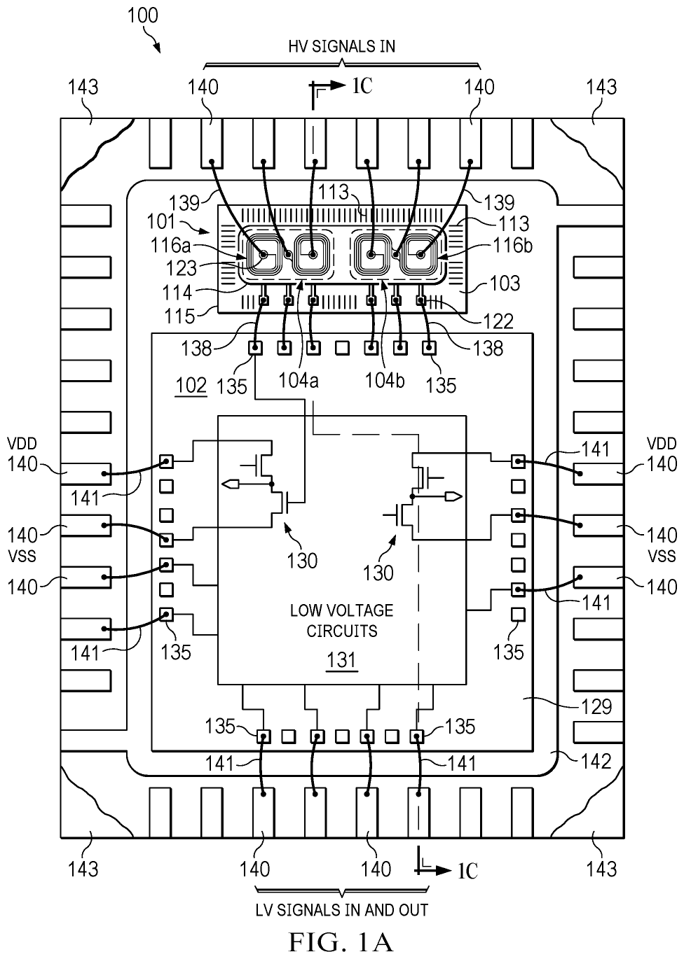

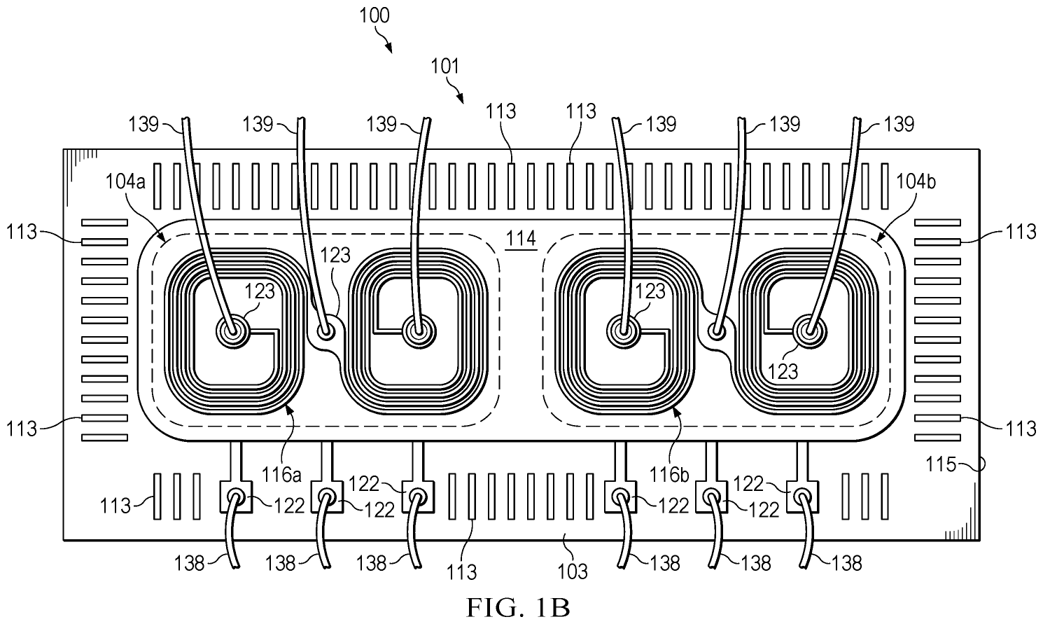

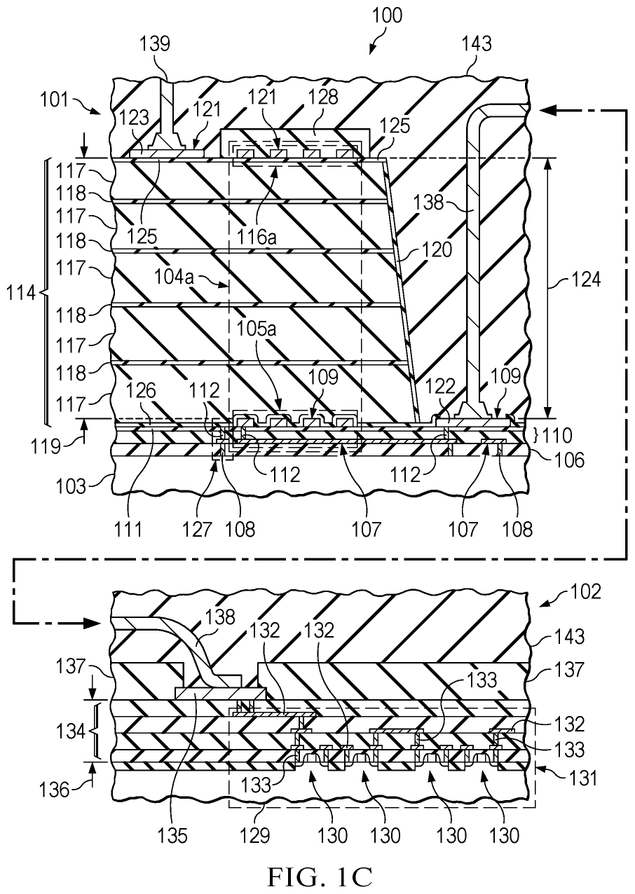

FIG. 1A through FIG. 1C are top views and a cross section, respectively, of an example microelectronic device having a galvanic isolation device. In this example, the microelectronic device (100) may be manifested as a multi-chip module (100) which includes the galvanic isolation device (101) and a semiconductor device (102). The galvanic isolation device (101) may, in some cases be referred to as a galvanic isolation component or a galvanic isolation chip.

The galvanic isolation device (101) includes a silicon substrate (103). The silicon substrate (103) may be manifested as a portion of a bulk silicon wafer, optionally having an epitaxial layer. The silicon substrate (103) may be manifested as a portion of a silicon-on-insulator (SOI) wafer.

The galvanic isolation device (101) of this example includes a first high voltage isolation component (104a) and a second high voltage isolation component (104b). FIG. 1B shows the galvanic isolation device (101) in more detail. The first high voltage isolation component (104a) includes a first lower isolation element (105a), shown in FIG. 1C, but obscured in FIG. 1A and FIG. 1B, over the silicon substrate (103). The second high voltage isolation component (104b) includes a second lower isolation element, obscured in FIG. 1A and FIG. 1B, and out of the plane of FIG. 1C, over the silicon substrate (103). In this example, the first lower isolation element (105a) and the second lower isolation element may be manifested as lower transformer windings. The first lower isolation element (105a) and the second lower isolation element may include primarily aluminum. The first lower isolation element (105a) and the second lower isolation element are separated from the silicon substrate (103) by a pre-metal dielectric (PMD) layer (106). In this example, the PMD layer (106) may include high stress silicon dioxide formed by a PECVD process using TEOS.

A portion of the first lower isolation element (105a) and a portion of the second lower isolation element may be elements of a first interconnect level (107) on the PMD layer (106). Elements of the first interconnect level (107) may include an adhesion layer, not specifically shown, of titanium or titanium tungsten on the PMD layer (106), a lower barrier layer, not specifically shown, of titanium nitride on the adhesion layer, a main layer, not specifically shown, of aluminum with 0.1 to 5 percent silicon, chromium, copper, or titanium, on the lower barrier layer, and an upper barrier layer, not specifically shown, of titanium nitride on the main layer. The main layer may be significantly thicker than the other layers, so that the elements of the first interconnect level (107), as a whole, may include primarily aluminum.

Some of the elements of the first interconnect level (107) may be connected to the silicon substrate (103) by contacts (108) that extend through the PMD layer (106). The contacts (108) may include an adhesion liner, not specifically shown, of titanium contacting the PMD layer (106) and the silicon substrate (103), a barrier liner, not specifically shown, of titanium nitride on the adhesion liner, and a core, not specifically shown, of tungsten on the barrier liner. Alternatively, the contacts (108) may include a core of aluminum or cobalt.

Another portion of the first lower isolation element (105a) and another portion of the second lower isolation element may be elements of a second interconnect level (109). Elements of the second interconnect level (109) may include layers that are similar to the layers of the first interconnect level (107). A main layer of the second interconnect level (109), that includes primarily aluminum, may be thicker than the main layer of the first interconnect level (107). The first high voltage isolation component (104a) may include a first ground ring, not specifically shown, of the second interconnect level (109) around the first lower isolation element (105a) and connected to the silicon substrate (103). Similarly, the first high voltage isolation component (104a) may include a second ground ring, not specifically shown, of the second interconnect level (109) around the second lower isolation element and connected to the silicon substrate (103).

The second interconnect level (109) may be separated from the first interconnect level (107) by an inter-level dielectric (ILD) layer (110) on the first interconnect level (107) and the PMD layer (106). The ILD layer (110) may include a high stress silicon dioxide sub-layer (111) extending to a top of the ILD layer (110).

Some of the elements of the second interconnect level (109) may be connected to some of the elements of the first interconnect level (107) by vias (112) that extend through the ILD layer (110). The vias (112) may include an adhesion liner, not specifically shown, of titanium contacting the ILD layer (110) and the elements of the first interconnect level (107), a barrier liner, not specifically shown, of titanium nitride on the adhesion liner, and a core, not specifically shown, of tungsten on the barrier liner.

The dielectric layers in the PMD layer (106) and the ILD layer (110) may have compressive stress. The elements of the first interconnect level (107) and the second interconnect level (109) may have tensile stress. The galvanic isolation device (101) may include pattern fill segments (113) of the first interconnect level (107) and/or the second interconnect level (109). The pattern fill segments (113) may be connected to the silicon substrate (103). The pattern fill segments (113) may be configured in linear arrays of line segments or two-dimensional arrays of rectangles. The tensile stress in the pattern fill segments (113) may advantageously reduce wafer bow of the silicon substrate (103) during fabrication of the galvanic isolation device (101) by partially compensating for the compressive stress in the PMD layer (106) and the ILD layer (110).

The galvanic isolation device (101) includes a dielectric plateau (114) over the first lower isolation element (105a) and the second lower isolation element. The dielectric plateau (114) does not extend to a perimeter (115) of the silicon substrate (103). The galvanic isolation device (101) includes a first upper isolation element (116a) of the first high voltage isolation component (104a) over the dielectric plateau (114), above the first lower isolation element (105a). The galvanic isolation device (101) includes a second upper isolation element (116b) of the second high voltage isolation component (104b) over the dielectric plateau (114), above the second lower isolation element. The dielectric plateau (114) of this example includes a plurality of low stress layers (117) of silicon dioxide-based dielectric material and a plurality of high stress layers (118) of silicon dioxide-based dielectric material. The low stress layers (117) may advantageously reduce bow or distortion in the silicon substrate (103). The high stress layers (118) may improve a mechanical strength of the dielectric plateau (114). The dielectric plateau (114) may further include one or more etch stop layers, not specifically shown, of silicon nitride-based dielectric materials, such as silicon nitride and silicon oxynitride. The dielectric plateau (114) comprises inorganic dielectric material extending from the first upper isolation element (116a) to the first lower isolation element (105a). Similarly, the dielectric plateau (114) comprises inorganic dielectric material extending from the second upper isolation element (116b) to the second lower isolation element. A plateau thickness (119) of the dielectric plateau (114) between the first upper isolation element (116a) and the first lower isolation element (105a) is sufficient to provide reliable operation of the galvanic isolation device (101) for an operational potential difference between the first upper isolation element (116a) and the first lower isolation element (105a), and between the second upper isolation element (116b) and the second lower isolation element. By way of example, the plateau thickness (119) may be 18 microns to 22 microns for an operational potential difference of 1000 volts. The operational potential difference is at least 400 volts rms. The dielectric plateau (114) may be free of electrically conductive material between the first upper isolation element (116a) and the first lower isolation element (105a), and between the second upper isolation element (116b) and the second lower isolation element.

The dielectric plateau (114) of this example includes a sidewall barrier layer (120) of nitridated silicon dioxide on lateral surfaces of the low stress layers (117) and the high stress layers (118) of silicon dioxide-based dielectric material. A nitrogen content of the sidewall barrier layer (120) decreases with a lateral distance into the dielectric plateau (114). The sidewall barrier layer (120) may reduce water infiltration into the dielectric plateau (114) and thereby advantageously increase reliability of the galvanic isolation device (101). Water infiltration into the dielectric plateau (114) may increase stress in the silicon dioxide based dielectric material and may also increase risk of cracks in the silicon dioxide based dielectric material.

In this example, the upper isolation elements (116a) and (116b) may be manifested as upper transformer windings. The upper isolation elements (116a) and (116b) may include primarily aluminum. The upper isolation elements (116a) and (116b) may be elements of a third interconnect level (121). The third interconnect level (121) may include layers that are similar to the layers of the second interconnect level (109). A main layer of the third interconnect level (121), that includes primarily aluminum, may be as thick, or thicker, than the main layer of the second interconnect level (109). The first lower isolation element (105a) and the first upper isolation element (116a) are configured to transfer first signals, and the second lower isolation element and the second upper isolation element (116b) are configured to transfer second signals.

The galvanic isolation device (101) includes lower bond pads (122) connected to the first lower isolation element (105a) and the second lower isolation element. The lower bond pads (122) are adjacent to the dielectric plateau (114), so that the dielectric plateau (114) does not extend to the lower bond pads (122). In this example, the lower bond pads (122) may include an electrically conductive material suitable for wire bonding, such as aluminum or gold. A portion or all of the lower bond pads (122) may be elements of the first interconnect level (107) or the second interconnect level (109).

The galvanic isolation device (101) includes upper bond pads (123) connected to the first upper isolation element (116a) and the second upper isolation element (116b). The upper bond pads (123) are over the dielectric plateau (114). In this example, the upper bond pads (123) may include an electrically conductive material suitable for wire bonding. A portion or all of the upper bond pads (123) may be elements of the third interconnect level (121). A vertical distance (124) between the upper bond pads (123) and the lower bond pads (122) is approximately the plateau thickness (119) of the dielectric plateau (114) between the first upper isolation element (116a) and the first lower isolation element (105a). That is, the vertical separation (124) between the lower bond pads (122) and the upper bond pads (123) may be greater 6 microns or may be approximately equal to the plateau thickness (119).

The dielectric plateau (114) of this example includes an upper field reduction layer (125) immediately below, and contacting, the upper isolation elements (116a) and (116b). The upper field reduction layer (125) may include an upper high dielectric constant sublayer, not specifically shown, of primarily silicon nitride, contacting the upper isolation elements (116a) and (116b). The upper field reduction layer (125) may include an upper intermediate dielectric constant sublayer, not specifically shown, of primarily silicon oxynitride, below the upper high dielectric constant sublayer. The upper high dielectric constant sublayer has a dielectric constant greater than 6.0, which is higher than dielectric constants of the upper intermediate dielectric constant sublayer and the low stress layers (117) and the high stress layers (118) of silicon dioxide-based dielectric material. The upper intermediate dielectric constant sublayer has a dielectric constant between the dielectric constant of the upper high dielectric constant sublayer and the dielectric constants of the low stress layers (117) and the high stress layers (118). The upper field reduction layer (125) may reduce an electric field at the upper isolation elements (116a) and (116b), especially at corners of the upper isolation elements (116a) and (116b), during operation of the galvanic isolation device (101), advantageously increasing a breakdown potential of the dielectric plateau (114).

The dielectric plateau (114) of this example includes a lower field reduction layer (126) immediately above, and contacting, the first lower isolation element (105a) and the second lower isolation element. The lower field reduction layer (126) may include a lower high dielectric constant sublayer, not specifically shown, of primarily silicon nitride, above, and contacting, the first lower isolation element (105a) and the second lower isolation element, and a lower intermediate dielectric constant sublayer, not specifically shown, of primarily silicon oxynitride, above the lower high dielectric constant sublayer. The lower high dielectric constant sublayer has a dielectric constant greater than 6.0, which is higher than dielectric constants of the lower intermediate dielectric constant sublayer and the low stress layers (117) and the high stress layers (118). The lower intermediate dielectric constant sublayer has a dielectric constant between the dielectric constant of the lower high dielectric constant sublayer and the dielectric constants of the low stress layers (117) and the high stress layers (118). The lower field reduction layer (126) may reduce an electric field at the first lower isolation element (105a) and the second lower isolation element, especially at corners of the first lower isolation element (105a) and the second lower isolation element, during operation of the galvanic isolation device (101), advantageously increasing a breakdown potential of the dielectric plateau (114).

The galvanic isolation device (101) of this example includes a field diversion structure (127) adjacent to the first lower isolation element (105a) and the second lower isolation element. The field diversion structure (127) is electrically conductive, inorganic, and is connected to the silicon substrate (103). A top surface of the field diversion structure (127) is substantially coplanar with a bottom surface of the second interconnect level (109) in the first lower isolation element (105a) and the second lower isolation element. For the purposes of this disclosure, the term “substantially coplanar” refers to surfaces that are coplanar within fabrication effects encountered during etching and polishing of layers of the microelectronic device. For example, the top surface of the field diversion structure (127) is substantially coplanar with the bottom surface of the bottom surface of the second interconnect level (109), notwithstanding the fact that the top surface of the field diversion structure (127) may extend slightly, that is, less than 50 nanometers, above or below a plane of the bottom surface of the bottom surface of the second interconnect level (109). The field diversion structure (127) of this example may include instances of the contacts (108) on the silicon substrate (103), one or more elements of the first interconnect level (107) on the contacts (108), and one or more stretched configurations of the vias (112) on the elements of the first interconnect level (107). The field diversion structure (127) of this example is separated from the first lower isolation element (105a) by a distance that is half a thickness of the second interconnect level (109) in the first lower isolation element (105a) to twice the thickness of the second interconnect level (109) in the first lower isolation element (105a). The field diversion structure (127) may divert the electric field away from edges of the first lower isolation element (105a) and the second lower isolation element toward adjacent areas of the silicon substrate (103) during operation of the galvanic isolation device (101), advantageously increasing the breakdown potential of the dielectric plateau (114) at corners of the first lower isolation element (105a) and the second lower isolation element.

The silicon substrate (103) may be free of an active component, which may advantageously reduce a cost of the galvanic isolation device (101). Alternatively, the galvanic isolation device (101) may include an active component or a circuit to boost signals through the first lower isolation element (105a) and/or the second lower isolation element, which may advantageously improve performance of the galvanic isolation device (101).

The galvanic isolation device (101) may include a protective overcoat (128), shown in FIG. 1C but omitted in FIG. 1A and FIG. 1B, over the upper isolation elements (116a) and (116b). The upper bond pads (123) are exposed by the protective overcoat (128). The protective overcoat (128) may include polyimide, and may provide protection for the upper isolation elements (116a) and (116b) during assembly of the galvanic isolation device (101) into the microelectronic device (100).

The semiconductor device (102) includes a semiconductor substrate (129) separate from the silicon substrate (103) of the galvanic isolation device (101). The semiconductor substrate (129) may include silicon, gallium nitride, or silicon carbide, by way of example. The semiconductor device (102) further includes one or more active components (130), depicted in FIG. 1A and FIG. 1B as MOS transistors. Other types of active components are within the scope of this example. The active components (130) may be parts of low voltage circuits (131) of the semiconductor device (102), that is, the semiconductor device (102) of this example is a low voltage chip. The active components (130) and the low voltage circuits (131) are configured to operate at circuit bias potentials close to a lower end of the operational potential difference between the first upper isolation element (116a) and the first lower isolation element (105a) of the galvanic isolation device (101). By way of example, the circuit bias potentials may be 5 volts to 30 volts.

The semiconductor device (102) includes one or more levels of interconnects (132) and electrically conductive contacts/vias (133) in an interconnect region (134) over the semiconductor substrate (129). The semiconductor device (102) includes device bond pads (135) over the interconnect region (134). Some of the device bond pads (135) are connected to the active components (130) through the interconnects (132) and contacts/vias (133). An interconnect region thickness (136) from the device bond pads (135) to the semiconductor substrate (129) is less than the plateau thickness (119). By way of example, the interconnect region thickness (136) may be less than half the plateau thickness (119). The semiconductor device (102) may include a protective overcoat (137) over the interconnect region (134). The device bond pads (135) are exposed by the protective overcoat (137).

The microelectronic device (100) of this example includes first electrical connections (138) connecting the lower bond pads (122) of the galvanic isolation device (101) to the device bond pads (135) of the semiconductor device (102). The microelectronic device (100) of this example includes second electrical connections (139) connecting the upper bond pads (123) of the galvanic isolation device (101) to a portion of external leads (140) of the microelectronic device (100), labeled “HV SIGNALS IN” in FIG. 1A. Additional instances of the external leads (140) are connected to instances of the device bond pads (135) by additional electrical connections (141). The additional instances of the external leads (140) may include instances of the external leads (140), labeled “VDD” in FIG. 1A, designated to provide power to the semiconductor device (102), and other instances of the external leads (140), labeled “VSS” in FIG. 1A, designated to provide a ground potential to the semiconductor device (102). Further instances of the external leads (140) may include instances of the external leads (140), labeled “LV SIGNALS IN AND OUT” in FIG. 1A, designated for signals into the semiconductor device (102) and signals from the semiconductor device (102). The first electrical connections (138), the second electrical connections (139), and the additional electrical connections (141) may be manifested as wire bonds, as indicated in FIG. 1A through FIG. 1C.

The galvanic isolation device (101) and the semiconductor device (102) may be located on a common die pad (142) of the microelectronic device (100), which may advantageously reduce cost and complexity compared to separate die pads. The silicon substrate (103) of the galvanic isolation device (101) may be electrically isolated from the common die pad (142) by an electrically insulating die attach material or bond wire, not shown. The semiconductor substrate (129) of the semiconductor device (102) may be electrically connected to the common die pad (142) by an electrically conductive die attach material, not shown. Alternatively, the semiconductor substrate (129) may be electrically isolated from the common die pad (142) by another electrically insulating die attach material, not shown.

The microelectronic device (100) may include a dielectric fill material (143), sometimes referred to as an encapsulation material, an injection mold compound, or a potting compound, on the galvanic isolation device (101) and the semiconductor device (102), surrounding the first electrical connections (138), the second electrical connections (139), and the additional electrical connections (141), and contacting the external leads (140) and the common die pad (142). The dielectric fill material (143) may include epoxy, for example, and may further include inorganic filler material such as aluminum oxide particles to reduce thermal expansion of the dielectric fill material (143). The dielectric fill material (143) is not shown in FIG. 1B to depict the galvanic isolation device (101) more clearly. The first electrical connections (138) may be formed with ultra-low loop (ULL) profiles to provide increased separation between the first electrical connections (138) on the lower bond pads (122) and the second electrical connections (139) on the upper bond pads (123), to reduce electrical stress in the dielectric fill material (143) during operation of the microelectronic device (100). Alternatively, the first electrical connections (138) may be formed with a stand-off stitch on ball (SSOB) bond on the lower bond pads (122) to provide the desired separation between the first electrical connections (138) and the second electrical connections (139). The second electrical connections (139) may have vertical wire configurations at the upper bond pads (123) to reduce electric field stress in the dielectric fill material (143).

During operation of the microelectronic device (100), power and ground are provided to the semiconductor device (102) through the “VDD” and “VSS” instances of the external leads (140). High voltage signals at potentials close to the operational potential difference are input to the upper bond pads (123) of the galvanic isolation device (101) through the “HV SIGNALS IN” instances of the external leads (140). The galvanic isolation device (101) generates low voltage signals at the lower isolation element (105a) from the high voltage signals, which are transferred to the semiconductor device (102) through the lower bond pads (122) and the first electrical connections (138). The low voltage signals are in a potential range that is compatible with the active component (130) of the semiconductor device (102).

Generating the low voltage signals with the combination of the galvanic isolation device (101) and the semiconductor device (102) may provide a lower cost of the microelectronic device (100) compared to integrating a high voltage isolation component into the semiconductor device (102), as explained above.

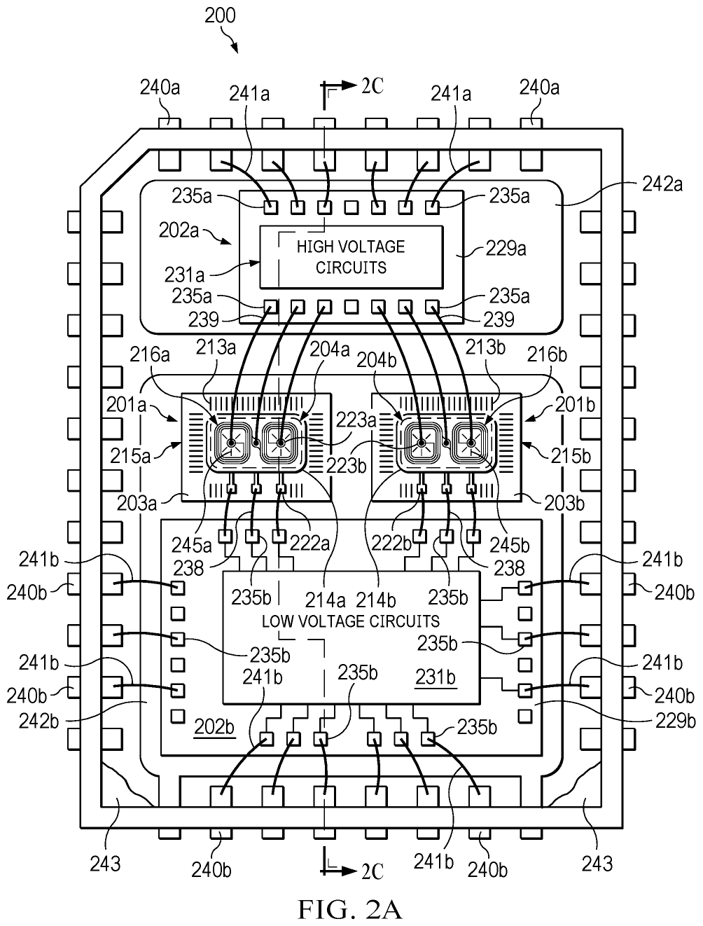

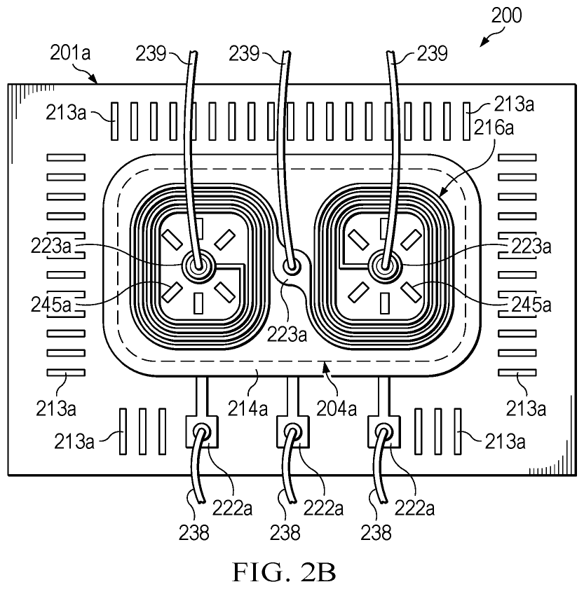

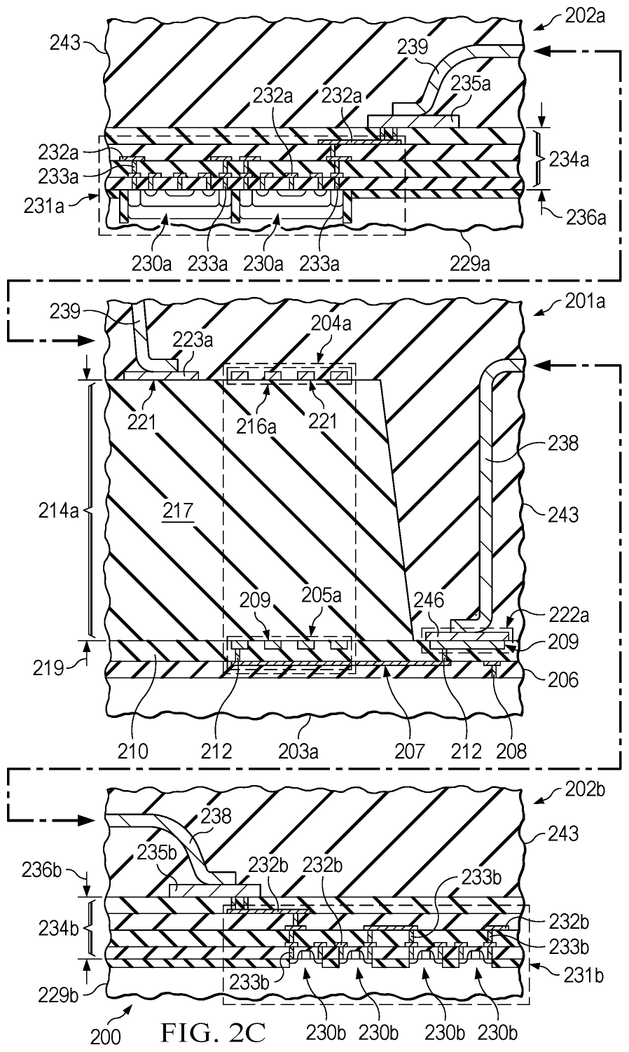

FIG. 2A through FIG. 2C are a top views and a cross section, respectively, of another example microelectronic device having two galvanic isolation devices. In this example, the microelectronic device (200) may be manifested as a multi-chip module (200) which includes a first galvanic isolation device (201a), a second galvanic isolation device (201b), a first semiconductor device (202a), and a second semiconductor device (202b).

The first galvanic isolation device (201a) includes a first silicon substrate (203a), and the second galvanic isolation device (201b) includes a second silicon substrate (203b), separate from the first silicon substrate (203a). The first galvanic isolation device (201a) includes a first high voltage isolation component (204a), and the second galvanic isolation device (201b) includes a second high voltage isolation component (204b).

The first high voltage isolation component (204a) includes a first lower isolation element (205a), shown in FIG. 2C but obscured in FIG. 2A and FIG. 2B, over the first silicon substrate (203a). The second high voltage isolation component (204b) includes a second lower isolation element, obscured in FIG. 2A and FIG. 2B, and out of the plane of FIG. 2C, over the second silicon substrate (203b). In this example, the first lower isolation element (205a) and the second lower isolation element may be manifested as lower transformer windings. The first lower isolation element (205a) may include primarily aluminum, or may include primarily copper, by way of example.

The first galvanic isolation device (201a) and the second galvanic isolation device (201b) may have similar designs, structures, and compositions. The first galvanic isolation device (201a) is shown in cross section in FIG. 2C. Elements, structures, and compositions disclosed for the first galvanic isolation device (201a) may be applied to the second galvanic isolation device (201b). The first lower isolation element (205a) is separated from the first silicon substrate (203a) by a PMD layer (206). A portion of the first lower isolation element (205a) may be part of a first interconnect level (207) of the first galvanic isolation device (201a). Some of the elements of the first interconnect level (207) may be connected to the first silicon substrate (203a) by contacts (208) that extend through the PMD layer (206). Another portion of the first lower isolation element (205a) may be part of a second interconnect level (209). The elements of the second interconnect level (209) may be thicker than the elements of the first interconnect level (207). The second interconnect level (209) may be separated from the first interconnect level (207) by an ILD layer (210) on the first interconnect level (207) and the PMD layer (206). Some of the elements of the second interconnect level (209) may be connected to some of the elements of the first interconnect level (207) by vias (212) that extend through the ILD layer (210).

The dielectric layers in the PMD layer (206) and the ILD layer (210) may have compressive stress. The elements of the first interconnect level (207) and the second interconnect level (209) may have tensile stress. The first galvanic isolation device (201a) may include first lower pattern fill segments (213a), shown in FIG. 2A and FIG. 2B, of the first interconnect level (207) and/or the second interconnect level (209). The second galvanic isolation device (201b) may include second lower pattern fill segments (213b), shown in FIG. 2A. The lower pattern fill segments (213a) and (213b) may be connected to the silicon substrates (203a) and (203b), respectively. The tensile stress in the lower pattern fill segments (213a) and (213b) may advantageously reduce wafer bow of the silicon substrates (203a) and (203b), respectively, during fabrication of the galvanic isolation devices (201a) and (201b).

The first galvanic isolation device (201a) includes a first dielectric plateau (214a) over the first lower isolation element (205a). The first dielectric plateau (214a) does not extend to a first perimeter (215a) of the first silicon substrate (203a). The first galvanic isolation device (201a) also includes a first upper isolation element (216a) of the first high voltage isolation component (204a), over the first dielectric plateau (214a), above the first lower isolation element (205a). The first dielectric plateau (214a) includes one or more layers of silicon dioxide-based dielectric material (217). The first dielectric plateau (214a) comprises inorganic dielectric material extending from the first upper isolation element (216a) to the first lower isolation element (205a). A first plateau thickness (219) of the first dielectric plateau (214a) between the first upper isolation element (216a) and the first lower isolation element (205a) is sufficient to provide reliable operation of the first galvanic isolation device (201a) for an operational potential difference of at least 400 volts rms between the first upper isolation element (216a) and the first lower isolation element (205a). The first dielectric plateau (214a) may be free of electrically conductive material between the first upper isolation element (216a) and the first lower isolation element (205a).

The second galvanic isolation device (201b) includes a second dielectric plateau (214b) over the second lower isolation element. The second dielectric plateau (214b) does not extend to a second perimeter (215b) of the second silicon substrate (203b). The second galvanic isolation device (201b) also includes a second upper isolation element (216b) of the second high voltage isolation component (204b), over the second dielectric plateau (214b), above the second lower isolation element. The second dielectric plateau (214b) may have a structure and composition similar to the structure and composition of the first dielectric plateau (214a).

In this example, the first upper isolation element (216a) may be manifested as a first upper transformer winding, and the second upper isolation element (216b) may be manifested as a second upper transformer winding. The first upper isolation element (216a) and the second upper isolation element (216b) may include primarily aluminum, or may include primarily copper, by way of example. The first upper isolation element (216a) may be part of a third interconnect level (221) of the first galvanic isolation device (201a). The third interconnect level (221) may have a layer structure similar to the layer structure of the second interconnect level (209). The first lower isolation element (205a) and the first upper isolation element (216a) are configured to transfer signals between the first lower isolation element (205a) and the first upper isolation element (216a).

The elements of the third interconnect level (221) may have tensile stress. The first galvanic isolation device (201a) may include first upper pattern fill segments (245a), shown in FIG. 2A and FIG. 2B, of the third interconnect level (221) over the first dielectric plateau (214a). The second galvanic isolation device (201b) may include second upper pattern fill segments (245b), shown in FIG. 2A, over the second dielectric plateau (214b). The tensile stress in the upper pattern fill segments (245a) and (245b) may advantageously reduce wafer bow of the silicon substrates (203a) and (203b), respectively, during fabrication of the galvanic isolation devices (201a) and (201b).

The first galvanic isolation device (201a) includes first lower bond pads (222a) connected to the first lower isolation element (205a). The first lower bond pads (222a) are adjacent to the first dielectric plateau (214a); the first dielectric plateau (214a) does not extend to the first lower bond pads (222a). In this example, the first lower bond pads (222a) may include electrically conductive pads (246) suitable for wire bonding, such as aluminum pads or gold pads. A portion or all of the first lower bond pads (222a) may be elements of the first interconnect level (207) or the second interconnect level (209). The second galvanic isolation device (201b) includes second lower bond pads (222b) connected to the second lower isolation element. The second lower bond pads (222b) are adjacent to the second dielectric plateau (214b); the second dielectric plateau (214b) does not extend to the second lower bond pads (222b).

The first galvanic isolation device (201a) includes first upper bond pads (223a) connected to the first upper isolation element (216a). The first upper bond pads (223a) are over the first dielectric plateau (214a). A portion or all of the first upper bond pads (223a) may be elements of the third interconnect level (221). A vertical separation between the first lower bond pads (222a) and the first upper bond pads (223a) may be greater 6 microns or may be approximately equal to the first plateau thickness (219a).

The second galvanic isolation device (201b) includes second upper bond pads (223b) connected to the second upper isolation element (216b). The second upper bond pads (223b) are over the second dielectric plateau (214b). A vertical separation between the second lower bond pads (222b) and the second upper bond pads (223b) may be greater 6 microns or may be approximately equal to a thickness of the second dielectric plateau (214b).

The first semiconductor device (202a) includes a first semiconductor substrate (229a) separate from the silicon substrates (203a) and (203b) of the galvanic isolation devices (201a) and (201b). The first semiconductor device (202a) further includes one or more first active components (230a), depicted FIG. 2C as bipolar transistors. Other types of active components are within the scope of this example. The first active components (230a) may be parts of high voltage circuits (231a) of the first semiconductor device (202a), that is, the first semiconductor device (202a) of this example is a high voltage chip. The first active components (230a) and the high voltage circuits (231a) are configured to operate at circuit bias potentials close to an upper end of the operational potential difference between the first upper isolation element (216a) and the first lower isolation element (205a) of the first galvanic isolation device (201a). That is, the first active components (230a) and the high voltage circuits (231a) are configured to operate at circuit bias potentials within 10 volts to 30 volts, for example, of the upper end of the operational potential difference, which may be 1000 volts, for example, above a ground potential of the microelectronic device (200).

The first semiconductor device (202a) includes one or more levels of first interconnects (232a) and first contacts/vias (233a) in a first interconnect region (234a) over the first semiconductor substrate (229a). The first semiconductor device (202a) includes first device bond pads (235a) over the first interconnect region (234a). Some of the first device bond pads (235a) are connected to the first active components (230a) through the first interconnects (232a) and first contacts/vias (233a). A first interconnect region thickness (236a) from the first device bond pads (235a) to the first semiconductor substrate (229a) is less than the first plateau thickness (219).

The second semiconductor device (202b) includes a second semiconductor substrate (229b) separate from the silicon substrates (203a) and (203b) of the galvanic isolation devices (201a) and (201b), and separate from the first semiconductor substrate (229a) of the first semiconductor device (202a). The second semiconductor device (202b) further includes one or more second active components (230b), depicted FIG. 2C as MOS transistors. Other types of active components are within the scope of this example. The second active components (230b) may be parts of low voltage circuits (231b) of the second semiconductor device (202b), that is, the second semiconductor device (202b) of this example is a low voltage chip. The second active components (230b) and the low voltage circuits (231b) are configured to operate at circuit bias potentials close to a lower end of the operational potential difference between the first upper isolation element (216a) and the first lower isolation element (205a) of the first galvanic isolation device (201a). That is, the second active components (230b) and the low voltage circuits (231b) are configured to operate at circuit bias potentials within 10 volts to 30 volts, for example, of the ground potential of the microelectronic device (200).

The second semiconductor device (202b) includes one or more levels of second interconnects (232b) and second contacts/vias (233b) in a second interconnect region (234b) over the second semiconductor substrate (229b). The second semiconductor device (202b) includes second device bond pads (235b) over the second interconnect region (234b). Some of the second device bond pads (235b) are connected to the second active components (230b) through the second interconnects (232b) and second contacts/vias (233b). A second interconnect region thickness (236b) from the second device bond pads (235b) to the second semiconductor substrate (229b) is less than the first plateau thickness (219).

The microelectronic device (200) of this example includes first electrical connections (238) connecting the second device bond pads (235b) of the second semiconductor device (202b) to the first lower bond pads (222a) of the first galvanic isolation device (201a) and to the second lower bond pads (222b) of the second galvanic isolation device (201b). The microelectronic device (200) of this example includes second electrical connections (239) connecting the first device bond pads (235a) of the first semiconductor device (202a) to the first upper bond pads (223a) of the first galvanic isolation device (201a) and to the second upper bond pads (223b) of the second galvanic isolation device (201b).

First additional electrical connections (241a) connect additional instances of the first device bond pads (235a) of the first semiconductor device (202a) to first external leads (240a) of the microelectronic device (200). During operation of the microelectronic device (200), the first additional electrical connections (241a) may provide high voltage power and high voltage ground to the first semiconductor device (202a); the high voltage power and high voltage ground are close to the operational potential difference between the first upper isolation element (216a) and the first lower isolation element (205a) of the first galvanic isolation device (201a). Second additional electrical connections (241b) connect additional instances of the second device bond pads (235b) of the second semiconductor device (202b) to second external leads (240b) of the microelectronic device (200). During operation of the microelectronic device (200), the second additional electrical connections (241b) may provide low voltage power and low voltage ground to the second semiconductor device (202b); the low voltage power and low voltage ground are close to the lower end of the operational potential difference between the first upper isolation element (216a) and the first lower isolation element (205a) of the first galvanic isolation device (201a). The first electrical connections (238), the second electrical connections (239), the first additional electrical connections (241a), and the second additional electrical connections (241b) may be manifested as ribbon bonds, as indicated in FIG. 2A through FIG. 2C.

The first semiconductor device (202a) may be located on a first die pad (242a) of the microelectronic device (200). The first die pad (242a) may be biased to a potential close to the upper end of the operational potential difference. The first galvanic isolation device (201a), the second galvanic isolation device (201b), and the second semiconductor device (202b) may be located on a second die pad (242b) of the microelectronic device (200), separate from the first die pad (242a). The second die pad (242b) may be biased to the ground potential of the microelectronic device (200), or to a potential close to the lower end of the operational potential difference.

The microelectronic device (200) may include a dielectric fill material (243) on the first galvanic isolation device (201a), the second galvanic isolation device (201b), the first semiconductor device (202a), and the second semiconductor device (202b), surrounding the first electrical connections (238), the second electrical connections (239), the first additional electrical connections (241a), and the second additional electrical connections (241b), and contacting the first die pad (242a) and the second die pad (242b). The dielectric fill material (243) is not shown in FIG. 2B to depict the first galvanic isolation device (201a) more clearly. The first electrical connections (238) may have low profiles near the lower bond pads (222a) and (222b), and the second electrical connections (239) may have substantially vertical configurations near the upper bond pads (223a) and (223b), to reduce electrical stress in the dielectric fill material (243) during operation of the microelectronic device (200).

During operation of the microelectronic device (200), high voltage signals at potentials close to the upper end of the operational potential difference are generated by the high voltage circuits (231a) in the first semiconductor device (202a). Some of the high voltage signals are transferred from the high voltage circuits (231a) through the first device bond pads (235a), through the second electrical connections (239), through the first upper bond pads (223a), to the first upper isolation element (216a) of the first galvanic isolation device (201a). Other high voltage signals are transferred from the high voltage circuits (231a) through the first device bond pads (235a), through the second electrical connections (239), through the second upper bond pads (223b), to the second upper isolation element (216b) of the second galvanic isolation device (201b).

The first galvanic isolation device (201a) and the second galvanic isolation device (201b) generate low voltage signals at the first lower isolation element (205a) and the second lower isolation element from the high voltage signals, which are transferred to the second semiconductor device (202b) through the first lower bond pads (222a) and the second lower bond pads (222b), the first electrical connections (238), and the second device bond pads (235b). The low voltage signals are around a potential that is compatible with the second active component (230b) of the second semiconductor device (202b). Generating the low voltage signals with the galvanic isolation devices (201a) and (201b) may provide a lower cost of the microelectronic device (200) compared to integrating a high voltage isolation component into either the first semiconductor device (202a) or the second semiconductor device (202b).

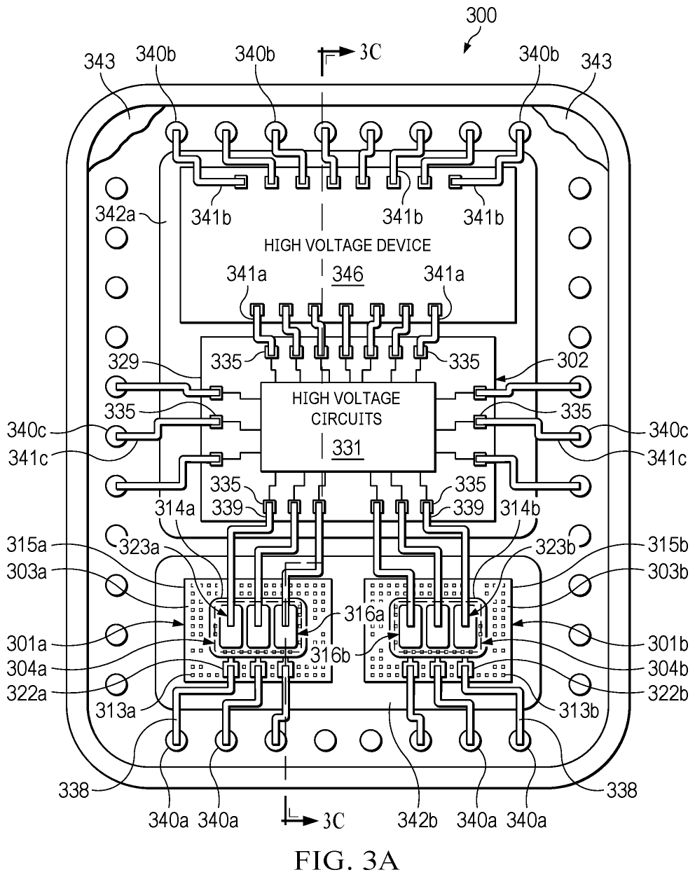

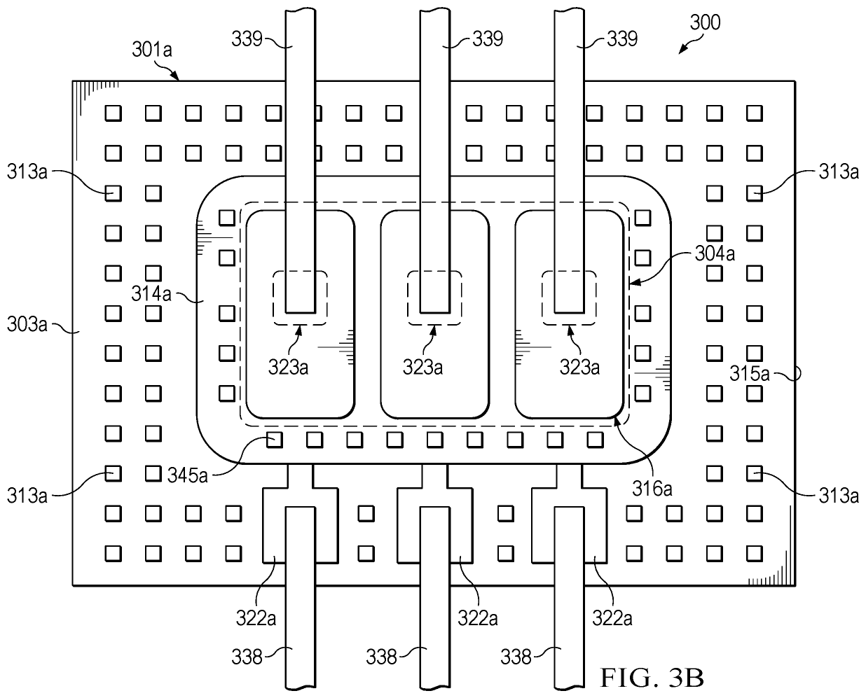

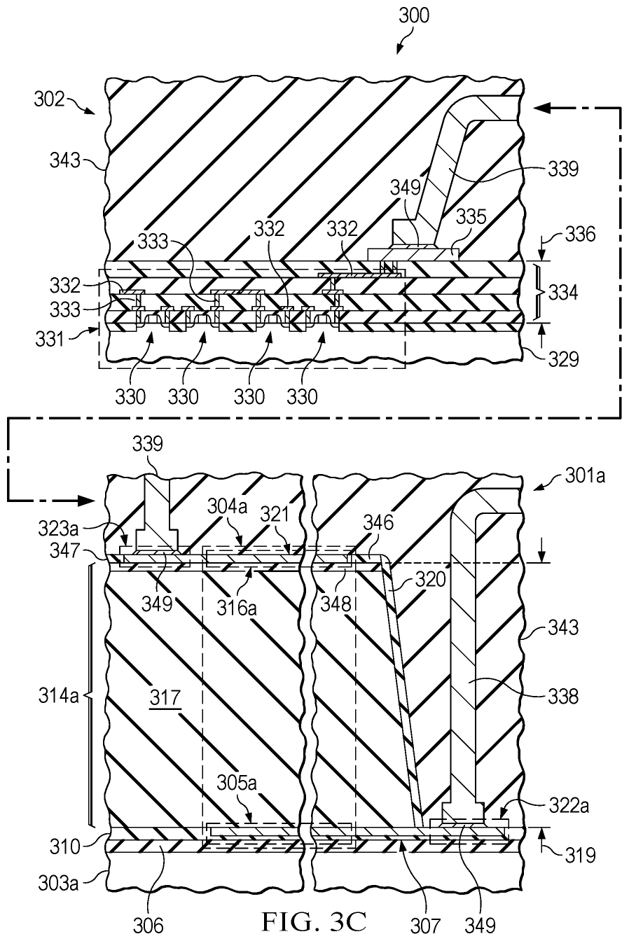

FIG. 3A through FIG. 3C are a top views and a cross section, respectively, of a further example microelectronic device having two galvanic isolation devices. In this example, the microelectronic device (300) may be manifested as a multi-chip module which includes a first galvanic isolation device (301a), a second galvanic isolation device (301b), a semiconductor device (302), and a high voltage device (346). The high voltage device (346) may be manifested as a sensor and/or an actuator, for example.

The first galvanic isolation device (301a) includes a first silicon substrate (303a), and the second galvanic isolation device (301b) includes a second silicon substrate (303b), separate from the first silicon substrate (303a). The first galvanic isolation device (301a) includes a plurality of first high voltage isolation components (304a), and the second galvanic isolation device (301b) includes a plurality of second high voltage isolation components (304b). In this example, the high voltage isolation components (304a) and (304b) may be manifested as isolation capacitors.

The first high voltage isolation component (304a) includes a first lower isolation element (305a), shown in FIG. 3C but obscured in FIG. 3A and FIG. 3B, over the first silicon substrate (303a). The second high voltage isolation component (304b) includes a second lower isolation element, obscured in FIG. 3A and FIG. 3B, and out of the plane of FIG. 3C, over the second silicon substrate (303b). In this example, the first lower isolation element (305a) and the second lower isolation element may be manifested as lower capacitor plates. The first lower isolation element (305a) may include primarily copper, or may include primarily aluminum, by way of example.

The first galvanic isolation device (301a) and the second galvanic isolation device (301b) may have similar designs, structures, and compositions. The first galvanic isolation device (301a) is shown in cross section in FIG. 3C. Elements, structures, and compositions disclosed for the first galvanic isolation device (301a) may be applied to the second galvanic isolation device (301b). The first lower isolation element (305a) is separated from the first silicon substrate (303a) by a PMD layer (306). In this example, the first lower isolation element (305a) may be an element of a first interconnect level (307) of the first galvanic isolation device (301a). The elements of the first interconnect level (307) may include primarily copper, and may be formed in a trench in an ILD layer (310) over the PMD layer (306). The elements of the first interconnect level (307) may include a barrier liner, not specifically shown, in the trench on the ILD layer (310), and a copper fill, not specifically shown, in the trench on the barrier liner. Alternatively, the elements of the first interconnect level (307) may include primarily aluminum.

The dielectric layers in the PMD layer (306) and the ILD layer (310) may have compressive stress. The elements of the first interconnect level (307) may have tensile stress. The first galvanic isolation device (301a) may include first lower pattern fill segments (313a), shown in FIG. 3A and FIG. 3B, of the first interconnect level (307). The second galvanic isolation device (301b) may include second lower pattern fill segments (313b), shown in FIG. 3A. The tensile stress in the lower pattern fill segments (313a) and (313b) may advantageously reduce wafer bow of the silicon substrates (303a) and (303b), respectively, during fabrication of the galvanic isolation devices (301a) and (301b).

The first galvanic isolation device (301a) includes a first dielectric plateau (314a) over the first lower isolation element (305a). The first dielectric plateau (314a) does not extend to a first perimeter (315a) of the first silicon substrate (303a). The first galvanic isolation device (301a) also includes a first upper isolation element (316a) of the first high voltage isolation component (304a), over the first dielectric plateau (314a), above the first lower isolation element (305a). The first dielectric plateau (314a) includes one or more layers of inorganic dielectric material (317). The first dielectric plateau (314a) comprises inorganic dielectric material extending from the first upper isolation element (316a) to the first lower isolation element (305a). A first plateau thickness (319) of the first dielectric plateau (314a) between the first upper isolation element (316a) and the first lower isolation element (305a) is sufficient to provide reliable operation of the first galvanic isolation device (301a) for an operational potential difference of at least 400 volts rms between the first upper isolation element (316a) and the first lower isolation element (305a). The first dielectric plateau (314a) may be free of electrically conductive material between the first upper isolation element (316a) and the first lower isolation element (305a). In this example, the first upper isolation element (316a) may be manifested as a first upper capacitor plate. The first upper isolation element (316a) may include primarily copper, and may be formed in an intra-metal dielectric (IMD) layer (347) of the first dielectric plateau (314a). The first upper isolation element (316a) may be part of a second interconnect level (321) of the first galvanic isolation device (301a). The elements of the second interconnect level (321) may include a barrier liner and copper fill, similar to the first interconnect level (307). The first lower isolation element (305a) and the first upper isolation element (316a) are configured to transfer signals between the first lower isolation element (305a) and the first upper isolation element (316a).

The first dielectric plateau (314a) of this example may include an upper barrier layer (348) under the IMD layer (347). In one version of this example, the upper barrier layer (348) may include silicon nitride, formed by a PECVD process using silane and ammonia or using bis(tertiary-butyl-amino)silane (BTBAS). In another version, the barrier layer (348) may include aluminum oxide formed by an atomic layer deposition (ALD) process using trimethylaluminum. The upper barrier layer (348) may provide an etch stop layer when forming the trench in the IMD layer (347) for the elements of the second interconnect level (321). The first dielectric plateau (314a) of this example may include a sidewall barrier layer (320) on lateral surfaces of the one or more layers of inorganic dielectric material (317). The sidewall barrier layer (320) may include silicon nitride or aluminum oxide, formed as a conformal layer on the first dielectric plateau (314a), followed by an anisotropic etch process, such as a reactive ion etch (RIE) process or ion mill process, to remove the conformal layer from horizontal surfaces, leaving a portion of the conformal layer on the lateral surfaces to provide the sidewall barrier layer (320). The upper barrier layer (348) and the sidewall barrier layer (320) may reduce water infiltration into the dielectric plateau (114).

The second galvanic isolation device (301b) includes a second dielectric plateau (314b) over the second lower isolation element. The second dielectric plateau (314b) does not extend to a second perimeter (315b) of the second silicon substrate (303b). The second galvanic isolation device (301b) also includes a second upper isolation element (316b) of the second high voltage isolation component (304b), over the second dielectric plateau (314b), above the second lower isolation element. The second dielectric plateau (314b) may have a structure and composition similar to the structure and composition of the first dielectric plateau (314a). The second upper isolation element (316b) may be manifested as a second upper capacitor plate.

The elements of the second interconnect level (321) may have tensile stress. The first galvanic isolation device (301a) may include first upper pattern fill segments (345a), shown in FIG. 3B, of the second interconnect level (321) over the first dielectric plateau (314a). The second galvanic isolation device (301b) may include second upper pattern fill segments, not specifically shown, over the second dielectric plateau (314b). The tensile stress in the first upper pattern fill segments (345a) and the second upper pattern fill segments may advantageously reduce wafer bow of the silicon substrates (303a) and (303b), respectively, during fabrication of the galvanic isolation devices (301a) and (301b).

The first galvanic isolation device (301a) includes first lower bond pads (322a) connected to the first lower isolation element (305a). The first lower bond pads (322a) are adjacent to the first dielectric plateau (314a); the first dielectric plateau (314a) does not extend to the first lower bond pads (322a). In this example, a portion or all of the first lower bond pads (322a) may be elements of the first interconnect level (307). The second galvanic isolation device (301b) includes second lower bond pads (322b) connected to the second lower isolation element. The second lower bond pads (322b) are adjacent to the second dielectric plateau (314b); the second dielectric plateau (314b) does not extend to the second lower bond pads (322b).

The first galvanic isolation device (301a) includes first upper bond pads (323a) connected to the first upper isolation element (316a). The first upper bond pads (323a) are over the first dielectric plateau (314a). A portion or all of the first upper bond pads (323a) may be elements of the second interconnect level (321). The second galvanic isolation device (301b) includes second upper bond pads (323b) connected to the second upper isolation element (316b). The second upper bond pads (323b) are over the second dielectric plateau (314b). Vertical separations between the lower bond pads (322a) and (322b), and the upper bond pads (323a) and (323b) may be greater 6 microns or may be approximately equal to thicknesses of the dielectric plateaus (314a) and (314b), respectively.

The semiconductor device (302) includes a semiconductor substrate (329) separate from the silicon substrates (303a) and (303b) of the galvanic isolation devices (301a) and (301b). The semiconductor device (302) further includes one or more active components (330), depicted FIG. 3C as MOS transistors. Other types of active components are within the scope of this example. The active components (330) may be parts of high voltage circuits (331) of the semiconductor device (302). The active components (330) and the high voltage circuits (331) are configured to operate at circuit bias potentials close to an upper end of the operational potential difference between the first upper isolation element (316a) and the first lower isolation element (305a) of the first galvanic isolation device (301a).

The semiconductor device (302) includes one or more levels of interconnects (332) and contacts/vias (333) in an interconnect region (334) over the semiconductor substrate (329). The semiconductor device (302) includes device bond pads (335) over the interconnect region (334). Some of the device bond pads (335) are connected to the active components (330) through the interconnects (332) and contacts/vias (333). An interconnect region thickness (336) from the device bond pads (335) to the semiconductor substrate (329) is less than the first plateau thickness (319).

The microelectronic device (300) of this example includes first electrical connections (338) connecting the first lower bond pads (322a) of the first galvanic isolation device (301a) and the second lower bond pads (322b) of the second galvanic isolation device (301b) to first external leads (340a) of the microelectronic device (300). The microelectronic device (300) of this example includes second electrical connections (339) connecting the device bond pads (335) of the semiconductor device (302) to the first upper bond pads (323a) of the first galvanic isolation device (301a) and to the second upper bond pads (323b) of the second galvanic isolation device (301b).

First additional electrical connections (341a) of the microelectronic device (300) connect additional instances of the device bond pads (335) of the semiconductor device (302) to the high voltage device (346). Second additional electrical connections (341b) of the microelectronic device (300) connect the high voltage device (346) to second external leads (340b) of the microelectronic device (300). During operation of the microelectronic device (300), the second additional electrical connections (341b) may provide power and ground to the high voltage device (346).

Third additional electrical connections (341c) connect additional instances of the device bond pads (335) of the semiconductor device (302) to third external leads (340c) of the microelectronic device (300). During operation of the microelectronic device (300), the third additional electrical connections (341c) may provide high voltage power and high voltage ground to the semiconductor device (302); the high voltage power and high voltage ground are close to the operational potential difference between the first upper isolation element (316a) and the first lower isolation element (305a) of the first galvanic isolation device (301a). The first electrical connections (338), the second electrical connections (339), the first additional electrical connections (341a), the second additional electrical connections (341b), and the third additional electrical connections (341c) may be manifested as clips, that are connected to the device bond pads (335), the upper bond pads (323a) and (323b), and the lower bond pads (322a) and (322b) through solder joints (349).

The semiconductor device (302) and the high voltage device (346) may be located on a first die pad (342a) of the microelectronic device (300). The first die pad (342a) may be biased to a potential close to the upper end of the operational potential difference. The first galvanic isolation device (301a) and the second galvanic isolation device (301b) may be located on a second die pad (342b) of the microelectronic device (300), separate from the first die pad (342a). The second die pad (342b) may be biased to the ground potential of the microelectronic device (300), or to a potential close to the lower end of the operational potential difference.

The microelectronic device (300) may include a dielectric fill material (343) on the first galvanic isolation device (301a), the second galvanic isolation device (301b), the semiconductor device (302), and the high voltage device (346), surrounding the first electrical connections (338), the second electrical connections (339), and the additional electrical connections (341a), (341b), and (341c), and contacting the external leads (340a), (340b), and (340c), and the die pads (342a) and (342b). The dielectric fill material (343) is not shown in FIG. 3B to depict the galvanic isolation device (301a) more clearly. The first electrical connections (338) may be formed with low profiles to provide increased separation from the second electrical connections (339), to reduce electrical stress in the dielectric fill material (343) during operation of the microelectronic device (300). The second electrical connections (339) may have vertical configurations at the upper bond pads (323a) and (332b) to reduce electric field stress in the dielectric fill material (343) between the second electrical connections (339) and the silicon substrates (303a) and (303b).

During operation of the microelectronic device (300), high voltage signals at potentials close to the upper end of the operational potential difference are generated by the high voltage circuits (331) in the semiconductor device (302). The high voltage signals are transferred from the high voltage circuits (331) through the device bond pads (335), through the second electrical connections (339), through the first upper bond pads (323a), to the first upper isolation element (316a) of the first galvanic isolation device (301a), and through the second electrical connections (339), through the second upper bond pads (323b), to the second upper isolation element (316b) of the second galvanic isolation device (301b). The first galvanic isolation device (301a) and the second galvanic isolation device (301b) generate low voltage signals at the first lower isolation element (305a) and the second lower isolation element from the high voltage signals, which are transferred from the first lower bond pads (322a) of the first galvanic isolation device (301a) and the second lower bond pads (322b) of the second galvanic isolation device (301b) through the first electrical connections (338) to the first external leads (340a) of the microelectronic device (300). The low voltage signals are at potentials close to the lower end of the operational potential difference.

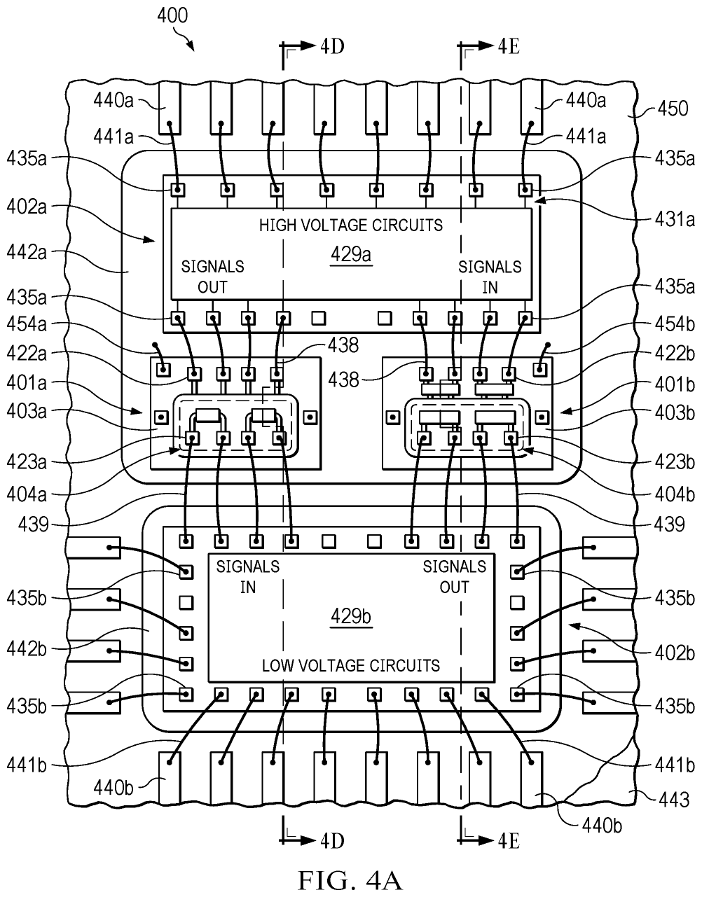

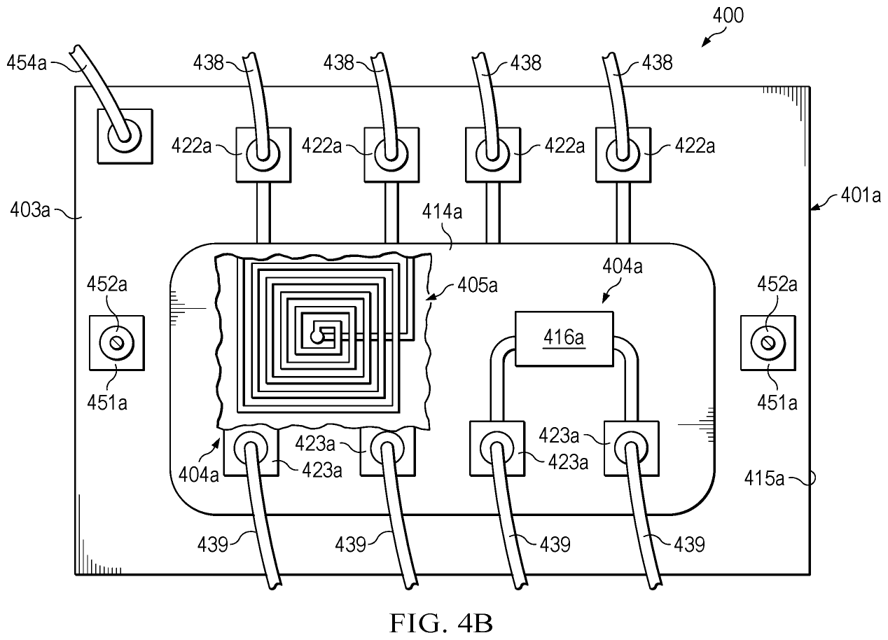

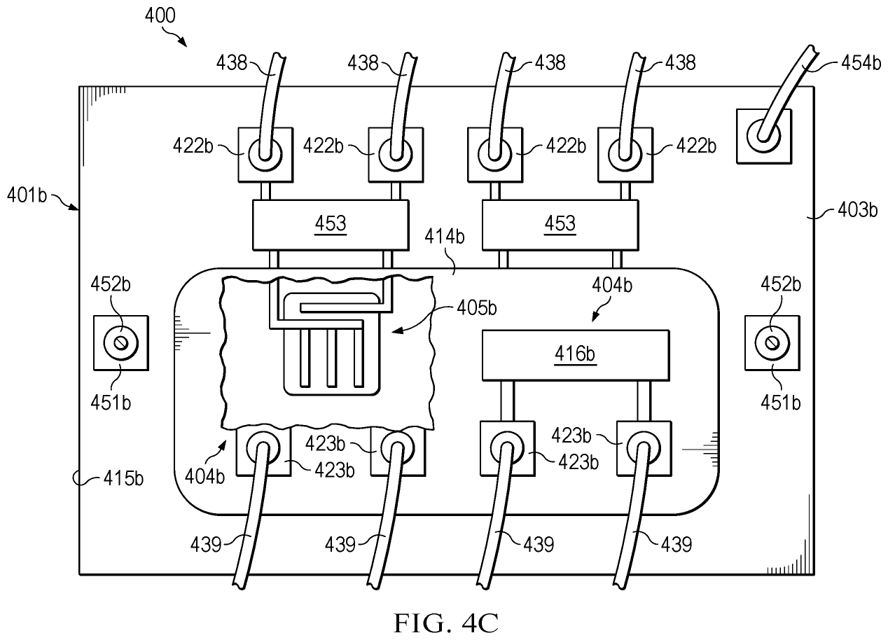

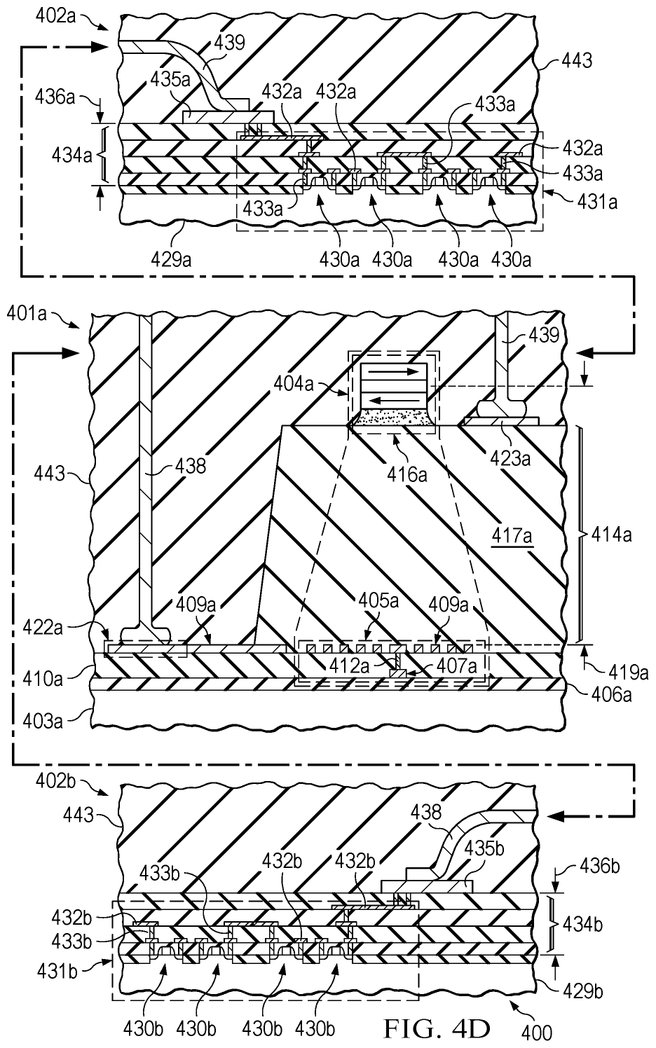

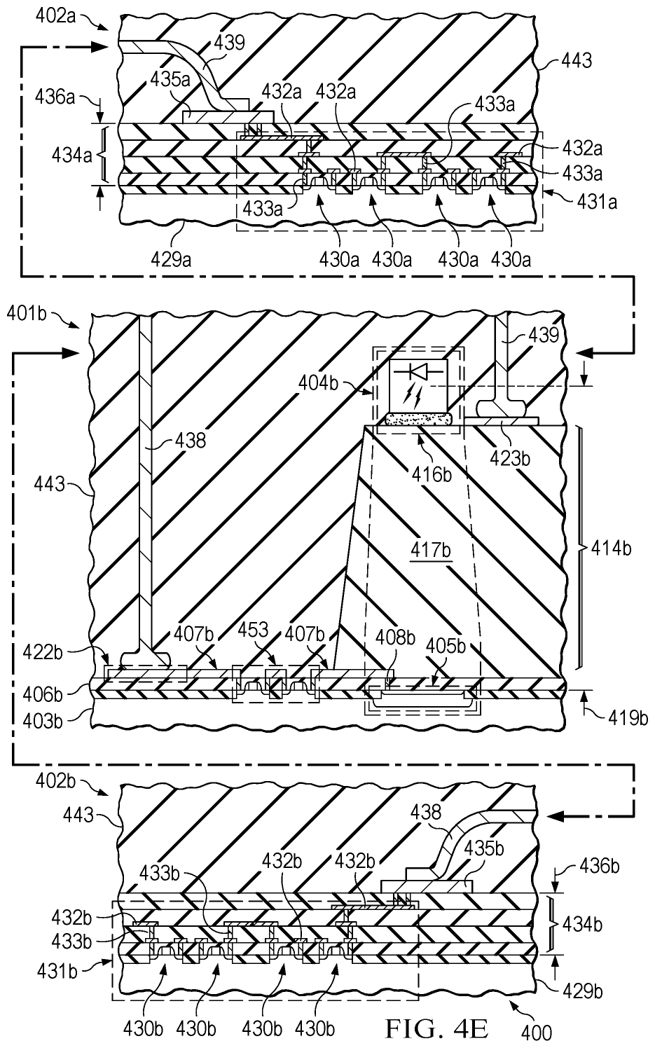

FIG. 4A through FIG. 4E are a top views and a cross section, respectively, of a further example microelectronic device having two galvanic isolation devices. In this example, the microelectronic device (400) may be manifested as a circuit board (450) having a first galvanic isolation device (401a), a second galvanic isolation device (401b), a first semiconductor device (402a), and a second semiconductor device (402b) attached to the circuit board (450). In this example, the first galvanic isolation device (401a), the second galvanic isolation device (401b), and the first semiconductor device (402a) may be attached to a high voltage die pad (442a), and the second semiconductor device (402b) may be attached to a low voltage die pad (442b). The first galvanic isolation device (401a) includes a plurality of first high voltage isolation components (404a), and the second galvanic isolation device (401b) includes a plurality of second high voltage isolation components (404b). During operation of the microelectronic device (400), high voltage signals from the first semiconductor device (402a) are sent to the first high voltage isolation components (404a), which generates low voltage signals from the high voltage signals and sends them to the second semiconductor device (402b). Also during operation of the microelectronic device (400), low voltage signals from the second semiconductor device (402b) are sent to the second high voltage isolation components (404b), which generates high voltage signals from the low voltage signals and sends them to the first semiconductor device (402a).

The first galvanic isolation device (401a) includes a first silicon substrate (403a). The first galvanic isolation device (401a) is shown in cross section in FIG. 4D. The first galvanic isolation device (401a) includes a first PMD layer (406a) over the first silicon substrate (403a). The first PMD layer (406a) may include silicon dioxide formed by a thermal oxidation process and silicon dioxide formed by a PECVD process. In this example, the first high voltage isolation components (404a) may be manifested as magnetic isolators. Each first galvanic isolation device (401a) includes a first lower isolation element (405a), shown in FIG. 4B and FIG. 4D but obscured in FIG. 4A, over the first PMD layer (406a). The first lower isolation element (405a) may be manifested as a magnetic driver coil, formed in a first interconnect level (407a) and a second interconnect level (409a) of the first galvanic isolation device (401a). The first interconnect level (407a) may be separated from the second interconnect level (409a) by a first ILD layer (410a) of the first galvanic isolation device (401a). The second interconnect level (409a) may include windings of the magnetic driver coil, and the first interconnect level (407a) may include a return line of the magnetic driver coil, connected to the windings through a first via (412a) of the first galvanic isolation device (401a).

The first galvanic isolation device (401a) includes a first dielectric plateau (414a) over the first lower isolation element (405a). The first dielectric plateau (414a) does not extend to a first perimeter (415a) of the first silicon substrate (403a). The first dielectric plateau (414a) includes one or more layers of inorganic dielectric material (417a).

Each first galvanic isolation device (401a) also includes a first upper isolation element (416a) of the first high voltage isolation component (404a), over the first dielectric plateau (414a), above the first lower isolation element (405a). The first upper isolation element (416a) may be manifested as a magnetic sensor, such as a magnetic tunnel junction, as depicted schematically in FIG. 4D. In this example, the first upper isolation element (416a) may be prefabricated and attached to the first dielectric plateau (414a), for example by a pick-and-place operation. The first upper isolation element (416a) may include material used to attach the first upper isolation element (416a) to the first dielectric plateau (414a).

The first dielectric plateau (414a) comprises inorganic dielectric material extending from the first upper isolation element (416a) to the first lower isolation element (405a). A first plateau thickness (419a) of the first dielectric plateau (414a) between the first upper isolation element (416a) and the first lower isolation element (405a) is sufficient to provide reliable operation of the first galvanic isolation device (401a) for a first operational potential difference of at least 400 volts rms between the first upper isolation element (416a) and the first lower isolation element (405a). The first dielectric plateau (414a) may be free of electrically conductive material between the first upper isolation element (416a) and the first lower isolation element (405a).

The first galvanic isolation device (401a) includes first lower bond pads (422a) connected to the first lower isolation element (405a). The first lower bond pads (422a) are adjacent to the first dielectric plateau (414a); the first dielectric plateau (414a) does not extend to the first lower bond pads (422a). The first galvanic isolation device (401a) includes first upper bond pads (423a) connected to the first upper isolation element (416a). The first upper bond pads (423a) are over the first dielectric plateau (414a). A vertical separation between the first lower bond pads (422a) and first upper bond pads (423a) may be greater 6 microns or approximately equal to a thickness of the first dielectric plateau (414a).

The second galvanic isolation device (401b) includes a second silicon substrate (403b). The second galvanic isolation device (401b) is shown in cross section in FIG. 4E. In this example, the second high voltage isolation components (404b) may be manifested as optical isolators. Each second galvanic isolation device (401b) includes a second lower isolation element (405b), shown in FIG. 4C and FIG. 4E but obscured in FIG. 4A, over the second PMD layer (406b). The second lower isolation element (405b) may be manifested as a photodetector, depicted in FIG. 4E as a doped well, formed in the second silicon substrate (403b). In this example, second galvanic isolation device (401b) may include signal processing components (453), depicted in FIG. 4E as MOS transistors, connected to the second lower isolation element (405b). The signal processing components (453) may provide a source follower, by way of example, for improving a sign-to-noise ratio of low voltage signals from the second lower isolation element (405b) during operation of the microelectronic device (400). The signal processing components (453) may be connected to the second lower isolation element (405b) through one or more contacts (408b) and elements of a first interconnect level (407b) of the second galvanic isolation device (401b). The second galvanic isolation device (401b) may include a second PMD layer (406b) over the second silicon substrate (403b), under the first interconnect level (407b).

The second galvanic isolation device (401b) includes a second dielectric plateau (414b) over the second lower isolation element (405b). The second dielectric plateau (414b) does not extend to a second perimeter (415b) of the second silicon substrate (403b). The second dielectric plateau (414b) includes one or more layers of inorganic dielectric material (417b). A vertical separation between the second lower bond pads (422b) and second upper bond pads (423b) may be greater 6 microns or approximately equal to a thickness of the second dielectric plateau (414b).

Each second galvanic isolation device (401b) also includes a second upper isolation element (416b) of the second high voltage isolation component (404b), over the second dielectric plateau (414b), above the second lower isolation element (405b). The second upper isolation element (416b) may be manifested as an optical emitter, such as a micro light emitting diode (LED), as depicted schematically in FIG. 4E. In this example, the second upper isolation element (416b) may be prefabricated and attached to the second dielectric plateau (414b). The second upper isolation element (416b) may include material used to attach the second upper isolation element (416b) to the second dielectric plateau (414b).

The second dielectric plateau (414b) comprises inorganic dielectric material extending from the second upper isolation element (416b) to the second lower isolation element (405b). A second plateau thickness (419b) of the second dielectric plateau (414b) between the second upper isolation element (416b) and the second lower isolation element (405b) is sufficient to provide reliable operation of the second galvanic isolation device (401b) for a second operational potential difference of at least 400 volts rms between the second upper isolation element (416b) and the second lower isolation element (405b). The second dielectric plateau (414b) may be free of electrically conductive material between the second upper isolation element (416b) and the second lower isolation element (405b).

The second galvanic isolation device (401b) includes second lower bond pads (422b) connected to the second lower isolation element (405b), through the signal processing components (453) in this example. The second lower bond pads (422b) are adjacent to the second dielectric plateau (414b); the second dielectric plateau (414b) does not extend to the second lower bond pads (422b). The second galvanic isolation device (401b) includes second upper bond pads (423b) connected to the second upper isolation element (416b). The second upper bond pads (423b) are over the second dielectric plateau (414b).

The first galvanic isolation device (401a) may include first bond shear test bond pads (451a) over the first silicon substrate (403a), laterally separated from the first dielectric plateau (414a). The first bond shear test bond pads (451a) are formed concurrently with the first lower bond pads (422a). First wire bond balls (452a) are formed on the first bond shear test bond pads (451a), which may advantageously enable in situ evaluation of wire bond ball shear strength. Similarly, the second galvanic isolation device (401b) may include second bond shear test bond pads (451b) over the second silicon substrate (403b), laterally separated from the second dielectric plateau (414b). Second wire bond balls (452b) are formed on the auxiliary lower bond pads (451b).

The first semiconductor device (402a) includes a first semiconductor substrate (429a) separate from the silicon substrates (403a) and (403b) of the galvanic isolation devices (401a) and (401b). The first semiconductor device (402a) further includes one or more first active components (430a), depicted FIG. 4D and FIG. 4E as MOS transistors. Other types of active components are within the scope of this example. The first active components (430a) may be parts of high voltage circuits (431a) of the first semiconductor device (402a). The first active components (430a) and the high voltage circuits (431a) are configured to operate at circuit bias potentials close to an upper end of the first operational potential difference between the first upper isolation element (416a) and the first lower isolation element (405a) of the first galvanic isolation device (401a), and close to an upper end of the second operational potential difference between the second upper isolation element (416b) and the second lower isolation element (405b) of the second galvanic isolation device (401b). The first semiconductor device (402a) includes one or more levels of first interconnects (432a) and first contacts/vias (433a) in a first interconnect region (434a) over the first semiconductor substrate (429a). The first semiconductor device (402a) includes first device bond pads (435a) over the first interconnect region (434a). Some of the first device bond pads (435a) are connected to the first active components (430a) through the first interconnects (432a) and first contacts/vias (433a). A first interconnect region thickness (436a) from the first device bond pads (435a) to the first semiconductor substrate (429a) is less than the first plateau thickness (419a) and less than the second plateau thickness (419b).

The second semiconductor device (402b) includes a second semiconductor substrate (429b) separate from the silicon substrates (403a) and (403b) of the galvanic isolation devices (401a) and (401b), and separate from the first semiconductor substrate (429a) of the first semiconductor device (402a). The second semiconductor device (402b) further includes one or more second active components (430b), depicted FIG. 4C as MOS transistors. Other types of active components are within the scope of this example. The second active components (430b) may be parts of low voltage circuits (431b) of the second semiconductor device (402b). The second active components (430b) and the low voltage circuits (431b) are configured to operate at circuit bias potentials close to a lower end of the first operational potential difference and close to a lower end of the second operational potential difference. The second semiconductor device (402b) includes one or more levels of second interconnects (432b) and second contacts/vias (433b) in a second interconnect region (434b) over the second semiconductor substrate (429b). The second semiconductor device (402b) includes second device bond pads (435b) over the second interconnect region (434b). Some of the second device bond pads (435b) are connected to the second active components (430b) through the second interconnects (432b) and second contacts/vias (433b). A second interconnect region thickness (436b) from the second device bond pads (435b) to the second semiconductor substrate (429b) is less than the first plateau thickness (419a) and less than the second plateau thickness (419b).

The microelectronic device (400) of this example includes first electrical connections (438) connecting the first device bond pads (435a) of the first semiconductor device (402a) to the first lower bond pads (422a) of the first galvanic isolation device (401a) and to the second lower bond pads (422b) of the second galvanic isolation device (401b). The microelectronic device (400) of this example includes second electrical connections (439) connecting the second device bond pads (435b) of the second semiconductor device (402b) to the first upper bond pads (423a) of the first galvanic isolation device (401a) and to the second upper bond pads (423b) of the second galvanic isolation device (401b).

First additional electrical connections (441a) connect additional instances of the first device bond pads (435a) of the first semiconductor device (402a) to first external leads (440a) of the microelectronic device (400). During operation of the microelectronic device (400), the first additional electrical connections (441a) may provide high voltage power and high voltage ground to the first semiconductor device (402a); the high voltage power and high voltage ground are close to the first operational potential difference between the first upper isolation element (416a) and the first lower isolation element (405a) of the first galvanic isolation device (401a) and the second operational potential difference between the second upper isolation element (416b) and the second lower isolation element (405b) of the second galvanic isolation device (401b). Second additional electrical connections (441b) connect additional instances of the second device bond pads (435b) of the second semiconductor device (402b) to second external leads (440b) of the microelectronic device (400). During operation of the microelectronic device (400), the second additional electrical connections (441b) may provide low voltage power and low voltage ground to the second semiconductor device (402b); the low voltage power and low voltage ground are close to the lower end of the first operational potential difference and close to the lower end of the second operational potential difference. The first electrical connections (438), the second electrical connections (439), the first additional electrical connections (441a), and the second additional electrical connections (441b) may be manifested as wire bonds, as indicated in FIG. 4A through FIG. 4E.

The microelectronic device (400) may include a dielectric fill material (443) on the galvanic isolation devices (401a) and (401b), and the semiconductor devices (402a) and (402b), surrounding the electrical connections (438), (439), (441a), and (441b), and contacting the external leads (440a), and (440b), and the die pads (442a) and (442b). The dielectric fill material (443) is not shown in FIG. 4B to depict the first galvanic isolation device (401a) more clearly. The first electrical connections (438) may be formed with low profiles to provide increased separation between the first electrical connections (438), and the second electrical connections (439), to reduce electrical stress in the dielectric fill material (443) during operation of the microelectronic device (400). The second electrical connections (439) may have vertical configurations at the upper bond pads (423) to reduce electric field stress in the dielectric fill material (443).

During operation of the microelectronic device (400), the high voltage die pad (442a), to which the first galvanic isolation device (401a), the second galvanic isolation device (401b), and the first semiconductor device (402a) are attached, may be biased to a potential close to the upper ends of the first and second operational potential differences. The first silicon substrate (403a) of the first galvanic isolation device (401a) may be connected to the high voltage die pad (442a) through a first substrate bias wire bond (454a). Similarly, the second silicon substrate (403b) of the second galvanic isolation device (401b) may be connected to the high voltage die pad (442a) through a second substrate bias wire bond (454b).

The low voltage die pad (442b), on which the second semiconductor device (402b) is located, may be biased to the ground potential of the microelectronic device (400), or to a potential close to the lower ends of the first and second operational potential differences.

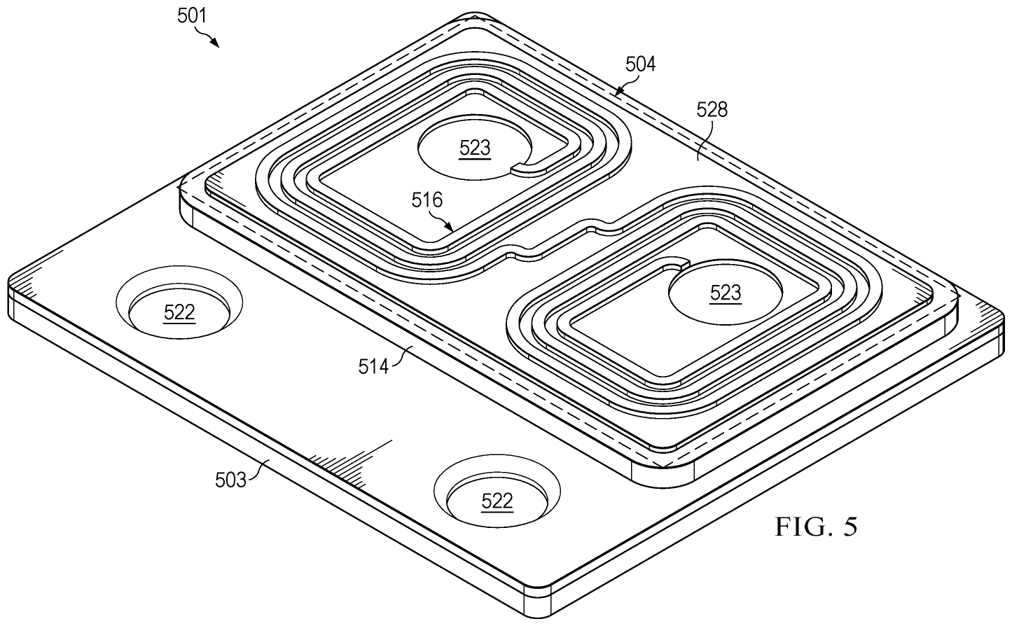

FIG. 5 is a perspective view of an example galvanic isolation device (501) in a standalone configuration. The galvanic isolation device (501) of this example includes a single high voltage isolation component (504). The standalone galvanic isolation device (501) is formed on a silicon substrate (503). The high voltage isolation component (504) is depicted as an isolation transformer, with an upper isolation element (516), manifested as an upper winding of the isolation transformer, and a lower isolation element, obscured in FIG. 5.

The lower isolation element is located over the silicon substrate (503). The galvanic isolation device (501) includes a dielectric plateau (514) between the lower isolation element and the upper isolation element (516). The dielectric plateau (514) comprises inorganic dielectric material extending from the lower isolation element to the upper isolation element (516). The dielectric plateau (514) may have any of the properties disclosed in reference to the dielectric plateau (114) of FIG. 1A through FIG. 1C, the dielectric plateaus (214a) and (214b) of FIG. 2A through FIG. 2C, the dielectric plateaus (314a) and (314b) of FIG. 3A through FIG. 3C, and the dielectric plateaus (414a) and (414b) of FIG. 4A through FIG. 4E.

The galvanic isolation device (501) includes lower bond pads (522) connected to the lower isolation element. The lower bond pads (522) are located over the silicon substrate (503), laterally separated from the dielectric plateau (514). The standalone galvanic isolation device (501) includes upper bond pads (523) connected to the upper isolation element (516). The upper bond pads (523) are located over the dielectric plateau (514). A vertical separation between the lower bond pads (522) and upper bond pads (523) may be greater 6 microns or approximately equal to a thickness of the dielectric plateau (514). The galvanic isolation device (501) may include a protective overcoat (528) over the upper isolation element (516). The upper bond pads (523) are exposed by the protective overcoat (528).

The galvanic isolation device (501) of this example may be sold in the standalone configuration. The galvanic isolation device (501) may be assembled in a microelectronic device, not shown, as disclosed in reference to any of the microelectronic device (100) of FIG. 1A through FIG. 1C, the microelectronic device (200) of FIG. 2A through FIG. 2C, the microelectronic device (300) of FIG. 3A through FIG. 3C, and the microelectronic device (400) of FIG. 4A through FIG. 4E.

In alternate versions of this example, the lower isolation element and the upper isolation element (516) may be manifested as any of the isolation elements (105a) and (116) of FIG. 1A through FIG. 1C, the isolation elements (205a), (205b), (216a), and (216b) of FIG. 2A through FIG. 2C, the isolation elements (305a), (316a), and (316b) of FIG. 3A through FIG. 3C, and the isolation elements (405a), (405b), (416a), and (416b) of FIG. 4A through FIG. 4E. In alternate versions of this example, the galvanic isolation device (501) may include additional instances of the high voltage isolation component (504).

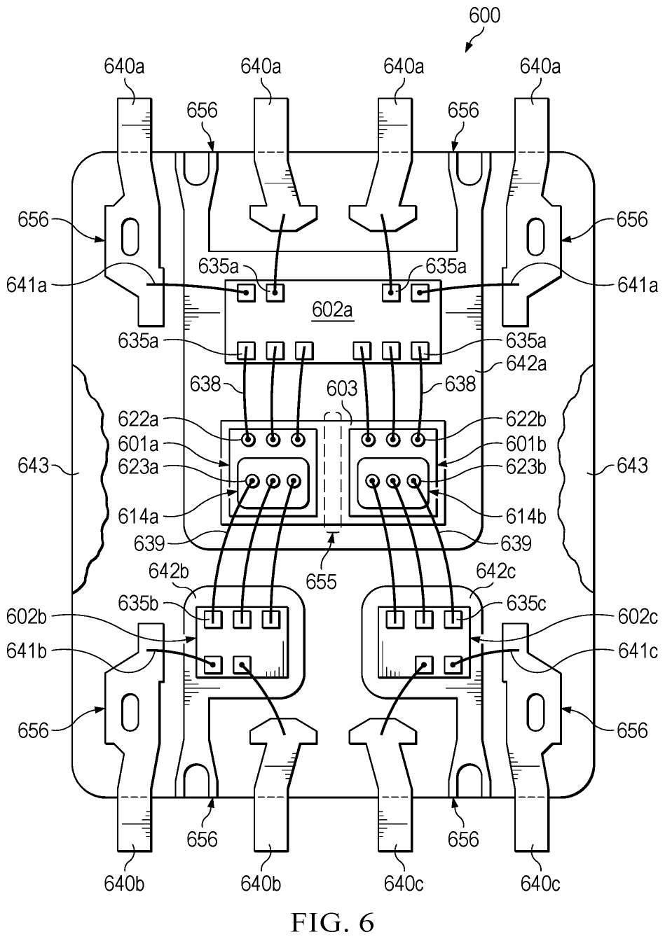

FIG. 6 is a top view of another example microelectronic device having two galvanic isolation devices. In this example, the microelectronic device (600) may be manifested in a small outline transistor (SOT) package. The SOT package may provide a desired form factor for the microelectronic device (600). The microelectronic device (600) includes a first galvanic isolation device (601a), a second galvanic isolation device (601b), a first semiconductor device (602a), a second semiconductor device (602b), and a third semiconductor device (602c). The first galvanic isolation device (601a) and the second galvanic isolation device (601b) may include isolation transformers, isolation capacitors, optical isolators, or magnetic isolators, by way of example.

The first galvanic isolation device (601a) and the second galvanic isolation device (601b) of this example share a common silicon substrate (603). The first galvanic isolation device (601a) and the second galvanic isolation device (601b) are separated by a singulation lane (655). The first galvanic isolation device (601a) and the second galvanic isolation device (601b) are fabricated concurrently with other galvanic isolation devices on a silicon wafer, with each galvanic isolation device separated from adjacent galvanic isolation devices by singulation lanes. After fabrication of the galvanic isolation devices is completed, the galvanic isolation devices are separated by cutting the silicon wafer along the singulation lanes. The silicon wafer may be cut by a saw process, a mechanical scribe process, a laser scribe process, or an etch process, for example. In this example, the first galvanic isolation device (601a) and the second galvanic isolation device (601b) are left connected; the process of cutting the silicon wafer does not cut through the singulation lane (655) between the first galvanic isolation device (601a) and the second galvanic isolation device (601b). The shared substrate configuration of the first galvanic isolation device (601a) and the second galvanic isolation device (601b) may advantageously enable a reduced size and thus a reduced cost of the microelectronic device (600). Forming each of the galvanic isolation devices on the silicon wafer with the singulation lanes between adjacent instances of the galvanic isolation devices may advantageously enable production of single galvanic isolation devices or multiple galvanic isolation devices on shared substrates using a single wafer fabrication sequence and adjusting the singulation process, reducing fabrication costs for the galvanic isolation devices.

The first galvanic isolation device (601a), the second galvanic isolation device (601b), and the first semiconductor device (602a) are attached to a first die pad (642a) of a lead frame (656) of the SOT package. The second semiconductor device (602b) is attached to a second die pad (642b) of a lead frame (656), and the third semiconductor device (602c) is attached to a third die pad (642c) of a lead frame (656), enabling the second semiconductor device (602b) and the third semiconductor device (602c) to operate at different potentials while exchanging information with the first semiconductor device (602a) through the first galvanic isolation device (601a) and the second galvanic isolation device (601b), respectively.

The first galvanic isolation device (601a) includes first lower bond pads (622a) over the silicon substrate (603), a first dielectric plateau (614a) over the silicon substrate (603), and first upper bond pads (623a) over the first dielectric plateau (614a). The first dielectric plateau (614a) does not extend to the first lower bond pads (622a), and does not extend to a perimeter of the first galvanic isolation device (601a). Similarly, the second galvanic isolation device (601b) includes second lower bond pads (622b) over the silicon substrate (603), a second dielectric plateau (614b) over the silicon substrate (603), and second upper bond pads (623b) over the second dielectric plateau (614b). Vertical separations between the lower bond pads (622a) and (622b), and the upper bond pads (623a) and (623b) may be greater 6 microns or may be approximately equal to thicknesses of the dielectric plateaus (614a) and (614b), respectively.

The second dielectric plateau (614b) does not extend to the second lower bond pads (622b), and does not extend to a perimeter of the second galvanic isolation device (601b). The first dielectric plateau (614a) and the second dielectric plateau (614b) may be manifested as disclosed in reference to the examples of FIG. 1A through FIG. 1C, FIG. 2A through FIG. 2C, FIG. 3A through FIG. 3C, or FIG. 4A through FIG. 4E.

The first semiconductor device (602a) includes first device bond pads (635a). The microelectronic device (600) includes first electrical connections (638) connecting a first portion of the first device bond pads (635a) to the first lower bond pads (622a) of the first galvanic isolation device (601a) and connecting a second portion of the first device bond pads (635a) to the second lower bond pads (622b) of the second galvanic isolation device (601b). The microelectronic device (600) also includes first additional electrical connections (641a) connecting a third portion of the first device bond pads (635a) to first external leads (640a) of the microelectronic device (600).

The second semiconductor device (602b) includes second device bond pads (635b). The microelectronic device (600) includes second electrical connections (639); a first portion of the second electrical connections (639) connect the first upper bond pads (623a) of the first galvanic isolation device (601a) to a first portion of the second device bond pads (635b). The microelectronic device (600) also includes second additional electrical connections (641b) connecting a second portion of the second device bond pads (635b) to second external leads (640b) of the microelectronic device (600).

The third semiconductor device (602c) includes third device bond pads (635c). A second portion of the second electrical connections (639) of the microelectronic device (600) connect the second upper bond pads (623b) of the second galvanic isolation device (601b) to a first portion of the third device bond pads (635c). The microelectronic device (600) also includes third additional electrical connections (641c) connecting a second portion of the third device bond pads (635c) to third external leads (640c) of the microelectronic device (600).

The first electrical connections (638) and the second electrical connections (639), as well as the additional electrical connections (641a), (641b), and (641c), may be implemented as wire ball bonds, ribbon bonds, or clips, by way of example. The microelectronic device (600) includes a dielectric fill material (643) on the galvanic isolation devices (601a) and (601b), and on the semiconductor devices (602a), (602b), and (602c), surrounding the first electrical connections (638), the second electrical connections (639), and the additional electrical connections (641a), (642b), and (642c), and contacting the external leads (640a), (640b), and (640c) and the die pad (642a), (642b), and (642c).

Various features of the examples disclosed herein may be combined in other manifestations of example microelectronic devices and galvanic isolation devices. For example, any of the microelectronic devices (100), (200), (300), or (400) may include a semiconductor device connected to the lower bond pads (122), (222a), (322a), or (422a) of the corresponding galvanic isolation devices (101), (201a), (301a), (401a), or (401b). Similarly, any of the microelectronic devices (100) through (400) may include a semiconductor device connected to the upper bond pads (123), (223a), (323a), or (423a) of the corresponding galvanic isolation devices (101) through (401a). Any of the microelectronic devices (100) through (400) may include one or more instances of the galvanic isolation devices (101) through (401b). Any of the galvanic isolation devices (101) through (401b) may include one or more instances of the corresponding high voltage isolation components (104a), (204a), (304a), (404a), or (404b). Any of the high voltage isolation components (104a) through (404b) may be manifested as an isolation transformer, an isolation capacitor, an optical isolator, or a magnetic isolator. Any of the galvanic isolation devices (101) through (401b) may include multiple layers of high stress silicon dioxide formed by PECVD processes using TEOS. Any of the galvanic isolation devices (101) through (401b) may include an upper field reduction layer immediately below, and contacting, the corresponding upper isolation elements (116a), (216a), (316a), (416a), or (416b). Any of the galvanic isolation devices (101) through (401b) may include a lower field reduction layer immediately above, and contacting, the lower isolation elements (105a), (205a), (305a), (405a), or (405b). Any of the dielectric plateaus (114), (214a), (314a), (414a), or (414b) may include a sidewall barrier layer on lateral surfaces of layers of inorganic dielectric material of the dielectric plateaus (114) through (414b). Any of the galvanic isolation devices (101) through (401b) may include a field diversion structure adjacent to the lower isolation elements (105a) through (405b). Any of the galvanic isolation devices (101) through (401b) may include lower pattern fill segments or upper pattern fill segments of interconnect levels of the galvanic isolation devices (101) through (401b). Any of the first electrical connections (138), (238), (338), or (438) and the second electrical connections (139), (239), (339), or (439) may be manifested as wire bonds, ribbon bonds, or clips.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a galvanic isolation device, including:
a silicon substrate;
an isolation component including a lower isolation element over silicon substrate;
an upper isolation element of the isolation component above the lower isolation element;
a dielectric plateau between the lower isolation element and the upper isolation element, wherein the dielectric plateau does not extend to a perimeter of silicon substrate, and the dielectric plateau comprises inorganic dielectric material extending from the upper isolation element to the lower isolation element;
lower bond pads adjacent to the dielectric plateau connected to the lower isolation element, wherein the dielectric plateau does not extend to the lower bond pads; and
upper bond pads over the dielectric plateau, connected to the upper isolation element;
a semiconductor device, including:
a semiconductor substrate separate from the silicon substrate;
an active component in the semiconductor substrate; and
device bond pads connected to the active component;
first electrical connections connecting to the lower bond pads; and
second electrical connections connecting to the upper bond pads;
wherein the device bond pads are connected to connections selected from the group consisting of the first electrical connections and the second electrical connections.

2. The microelectronic device of claim 1, wherein the dielectric plateau is thicker than an interconnect region of the semiconductor device.

3. The microelectronic device of claim 1, wherein the dielectric plateau includes more than 50 percent silicon dioxide-based dielectric material, by weight.

4. The microelectronic device of claim 1, wherein the galvanic isolation device further includes a second isolation component.

5. The microelectronic device of claim 1, further including a second galvanic isolation device.

6. The microelectronic device of claim 1, further including a second semiconductor device with second device bond pads connected to the galvanic isolation device.

7. The microelectronic device of claim 1, wherein the isolation component is an isolation transformer.

8. The microelectronic device of claim 1, wherein the silicon substrate is free of an active component.

9. The microelectronic device of claim 1, further including a dielectric fill material on the galvanic isolation device and the semiconductor device, surrounding the first electrical connections and the second electrical connections.

10. A galvanic isolation component, comprising:
a silicon substrate;
a lower isolation element over the silicon substrate;
an upper isolation element above the lower isolation element;
a dielectric plateau between the lower isolation element and the upper isolation element, wherein the dielectric plateau does not extend to a perimeter of the silicon substrate, wherein the dielectric plateau comprises inorganic dielectric material extending from the upper isolation element to the lower isolation element;
lower bond pads adjacent to the dielectric plateau, connected to the lower isolation element, wherein the dielectric plateau does not extend to the lower bond pads; and
upper bond pads over the dielectric plateau, connected to the upper isolation element.

11. The galvanic isolation component of claim 10, wherein the dielectric plateau is free of electrically conductive material between the upper isolation element and the lower isolation element.

12. The galvanic isolation component of claim 10, wherein the dielectric plateau includes more than 50 percent silicon dioxide-based dielectric material, by weight.

13. The galvanic isolation component of claim 10, wherein a plateau thickness of the dielectric plateau is greater than 8 microns.

14. The galvanic isolation component of claim 10, further including:
a second lower isolation element over the silicon substrate;
a second upper isolation element above the second lower isolation element, wherein the dielectric plateau extends between the second lower isolation element and the second upper isolation element;
second lower bond pads adjacent to the dielectric plateau, connected to the second lower isolation element, wherein the dielectric plateau does not extend to the second lower bond pads; and
second upper bond pads over the dielectric plateau, connected to the second upper isolation element.

15. The galvanic isolation component of claim 10, further including pattern fill conductors of an interconnect level containing the lower isolation element.

16. The galvanic isolation component of claim 10, wherein the lower isolation element is a lower winding of an isolation transformer, and the upper isolation element is an upper winding of the isolation transformer.

17. The galvanic isolation component of claim 10, further including a sidewall barrier layer on lateral surfaces of the dielectric plateau.

18. The galvanic isolation component of claim 10, wherein the silicon substrate is free of an active component.

19. The galvanic isolation component of claim 10, wherein there are two interconnect levels below the dielectric plateau.

20. The galvanic isolation component of claim 10, wherein the lower isolation element includes primarily aluminum.

21. A method of forming a galvanic isolation component, comprising:
forming lower bond pads over a substrate of the galvanic isolation component;
forming a lower isolation element over the substrate, the lower isolation element being connected to the lower bond pads;
forming a dielectric layer stack over the lower bond pads and the lower isolation element;
forming upper bond pads over the dielectric layer stack;
forming an upper isolation element over the dielectric layer stack, the upper isolation element being connected to the upper bond pads; and
patterning the dielectric layer stack by an etch process to form a dielectric plateau over the lower isolation element and under the upper isolation element and the upper bond pads, exposing the lower bond pads, wherein the dielectric plateau comprises inorganic dielectric material extending from the upper isolation element to the lower isolation element.

22. A method of forming a microelectronic device, comprising:
forming first electrical connections to lower bond pads of a galvanic isolation device of the microelectronic device, the lower bond pads being connected to a lower isolation element of the galvanic isolation device;
forming second electrical connections to upper bond pads of the galvanic isolation device, the upper bond pads being connected to an upper isolation element of the galvanic isolation device; and
forming electrical connections with either the first electrical connections or the second electrical connections to device bond pads of a semiconductor device of the microelectronic device; wherein:
the galvanic isolation device includes a dielectric plateau between the lower isolation element and the upper isolation element;
the dielectric plateau comprises inorganic dielectric material extending from the upper isolation element to the lower isolation element;
the dielectric plateau does not extend to a perimeter of a substrate of the galvanic isolation device; and
the dielectric plateau does not extend to the lower bond pads.

23. A microelectronic device, the microelectronic device being a multi-chip module and comprising:
a low voltage chip having a first bond pad on a first semiconductor substrate;
a high voltage chip having a second bond pad on a second semiconductor substrate;
a galvanic isolation chip having a transformer with an upper wiring connected to a third bond pad and a lower wiring connected to a fourth bond pad;
a first electrical connection between the third bond pad and the second bond pad;
a second electrical connection between the fourth bond pad and the first bond pad; and
a mold compound extending over the low voltage chip, the high voltage chip, and the galvanic isolation chip, wherein:
the upper wiring and the lower wiring are separated by an inorganic dielectric plateau extending from the lower wiring to the upper wiring;
the third bond pad is located over the inorganic dielectric plateau; and
the fourth bond pad located laterally adjacent to the inorganic dielectric plateau and at a first plane lower than a second plane of the third bond pad by a first distance greater than 6 microns.
